(19) United States
(12) Patent Application Publication
(10) Pub. No.: US 2026/0122373 A1
(43) Pub. Date: Apr. 30, 2026

(54) SOLID-STATE IMAGING ELEMENT, IMAGING DEVICE, AND CONTROL METHOD OF SOLID-STATE IMAGING ELEMENT

(71) Applicant: Sony Semiconductor Solutions Corporation, Kanagawa (JP)

(72) Inventors: Koji Nunomura, Kanagawa (JP); Yoshimichi Kumagai, Kanagawa (JP)

(21) Appl. No.: 19/121,318

(22) PCT Filed: Oct. 10, 2023
(86) PCT No.: PCT/JP2023/036748

§ 371 Date: Apr. 15, 2025

(30) Foreign Application Priority Data
Nov. 29, 2022 (JP) 2022-189736

(51) Int. Cl. H04N 25/771; H04N 25/532; H04N 25/59; H04N 25/621; H10F 39/00

(52) U.S. Cl. CPC H04N 25/771; H04N 25/532; H04N 25/59; H04N 25/621; H10F 39/8037

(57) ABSTRACT

Dynamic range expansion in a solid-state imaging element using a global shutter is disclosed. In one example, a solid-state imaging element includes a first transfer transistor, a second transfer transistor, and an overflow gate. The first transfer transistor transfers a charge from a photoelectric conversion element to a charge holding section. The second transfer transistor transfers a charge from one of the charge holding section and the photoelectric conversion element to a first floating diffusion layer. The overflow gate causes a second floating diffusion layer to hold a charge having overflowed from the photoelectric conversion element.

### TECHNICAL FIELD

The present technology relates to a solid-state imaging element. More particularly, the present technology relates to a solid-state imaging element including an analog memory for each pixel, an imaging device, and a control method of the solid-state imaging element.

### BACKGROUND ART

Conventionally, a global shutter method in which exposure starts and ends simultaneously for all pixels may be used in a solid-state imaging element because there is no rolling shutter distortion and it is suitable for imaging of a moving object. For example, there has been proposed a solid-state imaging element in which an analog memory is disposed at a preceding stage of floating diffusion (FD) and a charge from a photoelectric conversion element is transferred to the analog memory (See, for example, Patent Document 1.). In this solid-state imaging element, reading is sequentially executed row by row, and a charge is held in the analog memory of the selected row over a time from the end of exposure to reading of the selected row.

### CITATION LIST

### Patent Document

Patent Document 1: Japanese Translation of PCT International Application Publication No. 2017-536780

### SUMMARY OF THE INVENTION

### Problems to be Solved by the Invention

In the above-described conventional technique, the global shutter method is realized by controlling the analog memory to hold the charge over the time from the end of the exposure to the reading of the selected row. However, in the above-described solid-state imaging element, it is difficult to expand a dynamic range. By imaging a plurality of pieces of image data with different exposure times and synthesizing them, the dynamic range can be expanded, but it is not preferable since the number of captured images and power consumption increase.

The present technology has been created in view of such a situation, and an object of the present technology is to expand a dynamic range in a solid-state imaging element in which a global shutter method is used.

### Solutions to Problems

The present technology has been made to solve the above-described problems, and a first aspect thereof is a solid-state imaging element including: a first transfer transistor that transfers a charge from a photoelectric conversion element to a charge holding section; a second transfer transistor that transfers a charge from one of the charge holding section and the photoelectric conversion element to a first floating diffusion layer; and an overflow gate that causes a second floating diffusion layer to hold a charge having overflowed from the photoelectric conversion element, and a control method thereof. This brings about an effect that a dynamic range is expanded.

Furthermore, in the first aspect, the second transfer transistor may transfer a charge from the charge holding section to the first floating diffusion layer, and the overflow gate may cause the second floating diffusion layer to hold a charge having overflowed from the photoelectric conversion element. This brings about an effect that a signal according to a voltage of the second floating diffusion layer is read as a signal at the time of overflow.

Furthermore, in the first aspect, a first source follower circuit that amplifies and outputs a voltage of the first floating diffusion layer, and a second source follower circuit that amplifies and outputs a voltage of the second floating diffusion layer may be further included. This brings about an effect that signals obtained by amplifying the voltages of the first and second floating diffusion layers are simultaneously read out.

Furthermore, in the first aspect, a source follower circuit that amplifies and outputs a voltage of the second floating diffusion layer may be further included, and the first floating diffusion layer may be connected to the second floating diffusion layer. This brings about an effect that the number of source follower circuits is reduced.

Furthermore, in the first aspect, a conversion efficiency control transistor that opens and closes a path between the first floating diffusion layer and a third floating diffusion layer, a connection transistor that opens and closes a path between the second floating diffusion layer and the third floating diffusion layer, and a source follower circuit that amplifies and outputs a voltage of the first floating diffusion layer may be further included. This brings about an effect that the pipeline operation is realized.

Furthermore, in the first aspect, a capacitance value of the third floating diffusion layer may be 10 times or more a capacitance value of any one of the first and second floating diffusion layers. This brings about an effect that noise is reduced.

Furthermore, in the first aspect, a plurality of pixel circuits may share the first floating diffusion layer and the source follower circuit, and the photoelectric conversion element, the second and third floating diffusion layers, the charge holding section, the first and second transfer transistors, the overflow gate, and the conversion efficiency control transistor may be disposed in each of the plurality of pixel circuits. This brings about an effect that a circuit scale per pixel is reduced.

Furthermore, in the first aspect, a first source follower circuit that amplifies a voltage of the first floating diffusion layer and outputs the amplified voltage as a first voltage, a second source follower circuit that amplifies a voltage of the second floating diffusion layer and outputs the amplified voltage as a second voltage, and a sample hold circuit that holds the second voltage may be further included. This brings about an effect that image quality is improved.

Furthermore, in the first aspect, the second voltage may include: a reset level when the second floating diffusion layer is initialized; and a signal level according to an amount of charges accumulated in the second floating diffusion layer, and the sample hold circuit may include: a first capacitive element that holds the reset level; and a second capacitive element that holds the signal level. This brings about an effect that correlated double sampling (CDS) processing is executed.

Furthermore, in the first aspect, the second voltage may include: a reset level when the second floating diffusion layer is initialized; and a signal level according to an amount of charges accumulated in the second floating diffusion layer, the reset level may include first and second reset levels having conversion efficiencies different from each other for converting charges into voltages, the signal level may include first and second signal levels having the conversion efficiencies different from each other, and the sample hold circuit may include a plurality of capacitive elements that holds the first and second reset levels and the first and second signal levels, respectively. This brings about an effect that the dynamic range is further expanded.

Furthermore, in the first aspect, the second transfer transistor may transfer a charge from the photoelectric conversion element to the first floating diffusion layer, the first transfer transistor may transfer a charge having overflowed from the photoelectric conversion element to the charge holding section, and the overflow gate may transfer the overflowed charge from the charge holding section to the second floating diffusion layer and causes the second floating diffusion layer to hold the charge. This brings about an effect that deterioration of linearity is suppressed.

Furthermore, a second aspect of the present technology is an imaging device including: a first transfer transistor that transfers a charge from a photoelectric conversion element to a charge holding section; a second transfer transistor that transfers a charge from one of the charge holding section and the photoelectric conversion element to a first floating diffusion layer; an overflow gate that causes the second floating diffusion layer to hold a charge having overflowed from the photoelectric conversion element; and a signal processing circuit that synthesizes a first pixel signal according to a voltage of the first floating diffusion layer and a second pixel signal according to a voltage of the second floating diffusion layer. This brings about an effect that a dynamic range of an image captured by the imaging device is expanded.

### BRIEF DESCRIPTION OF DRAWINGS

FIG. 1 is a block diagram illustrating a configuration example of an imaging device according to a first embodiment of the present technology.

FIG. 2 is a block diagram illustrating a configuration example of a solid-state imaging element according to the first embodiment of the present technology.

FIG. 3 is a circuit diagram illustrating a configuration example of a pixel according to the first embodiment of the present technology.

FIG. 4 is a block diagram illustrating a configuration example of a column signal processing circuit according to the first embodiment of the present technology.

FIG. 5 is a timing chart illustrating an example of exposure control of the solid-state imaging element according to the first embodiment of the present technology.

FIG. 6 is a timing chart illustrating an example of a read operation of the solid-state imaging element according to the first embodiment of the present technology.

FIG. 7 is an example of a potential diagram of the pixel according to the first embodiment of the present technology.

FIG. 8 is a flowchart illustrating an example of an operation of the solid-state imaging element according to the first embodiment of the present technology.

FIG. 9 is a circuit diagram illustrating a configuration example of a pixel according to a second embodiment of the present technology.

FIG. 10 is a timing chart illustrating an example of exposure control of a solid-state imaging element according to the second embodiment of the present technology.

FIG. 11 is a timing chart illustrating an example of a read operation of the solid-state imaging element according to the second embodiment of the present technology.

FIG. 12 is an example of a potential diagram of a pixel according to the second embodiment of the present technology.

FIG. 13 is a circuit diagram illustrating a configuration example of a pixel according to a third embodiment of the present technology.

FIG. 14 is a timing chart illustrating an example of exposure control of a solid-state imaging element according to the third embodiment of the present technology.

FIG. 15 is a timing chart illustrating an example of a read operation of the solid-state imaging element according to the third embodiment of the present technology.

FIG. 16 is an example of a potential diagram of the pixel according to the third embodiment of the present technology.

FIG. 17 is a circuit diagram illustrating a configuration example of a pixel block in a fourth embodiment of the present technology.

FIG. 18 is a circuit diagram illustrating a configuration example of a pixel according to a fifth embodiment of the present technology.

FIG. 19 is a timing chart illustrating an example of exposure control of a solid-state imaging element according to the fifth embodiment of the present technology.

FIG. 20 is a timing chart illustrating an example of a read operation of the solid-state imaging element according to the fifth embodiment of the present technology.

FIG. 21 is an example of a potential diagram of the pixel according to the fifth embodiment of the present technology.

FIG. 22 is a circuit diagram illustrating a configuration example of a pixel according to a sixth embodiment of the present technology.

FIG. 23 is a circuit diagram illustrating a configuration example of a sample hold circuit according to a first modification of the sixth embodiment of the present technology.

FIG. 24 is a circuit diagram illustrating a configuration example of a sample hold circuit according to a second modification of the sixth embodiment of the present technology.

FIG. 25 is a circuit diagram illustrating a configuration example of a sample hold circuit according to a third modification of the sixth embodiment of the present technology.

FIG. 26 is a circuit diagram illustrating a configuration example of a pixel according to a seventh embodiment of the present technology.

FIG. 27 is a circuit diagram illustrating a configuration example of a sample hold circuit according to the seventh embodiment of the present technology.

FIG. 28 is a timing chart illustrating an example of exposure control of a solid-state imaging element according to the seventh embodiment of the present technology.

FIG. 29 is an example of a potential diagram of the pixel according to the seventh embodiment of the present technology.

FIG. 30 is a block diagram illustrating a schematic configuration example of a vehicle control system.

FIG. 31 is an explanatory diagram illustrating an example of an installation position of an imaging section.

### MODE FOR CARRYING OUT THE INVENTION

Modes for carrying out the present technology (hereinafter, referred to as embodiments) will be described below. The description will be given in the following order.
1. First embodiment (Example of holding overflowed charge in one of two FDs)
2. Second embodiment (Example of reducing source follower circuit and holding overflowed charge in one of two FDs)
3. Third embodiment (Example in which overflowed charge is held in one of two FDs and pipeline operation is performed)
4. Fourth embodiment (Example of causing one of two FDs to hold overflowed charge and sharing FD)
5. Fifth embodiment (Example of holding overflowed charge in analog memory)
6. Sixth embodiment (Example of holding overflowed charge in one of two FDs and sampling and holding level)
7. Seventh embodiment (Example in which overflowed charge is held in one of two FDs, conversion efficiency is switched, and a level is sampled and held)
8. Application example to mobile body

### 1. First Embodiment

### [Configuration Example of Imaging Device]

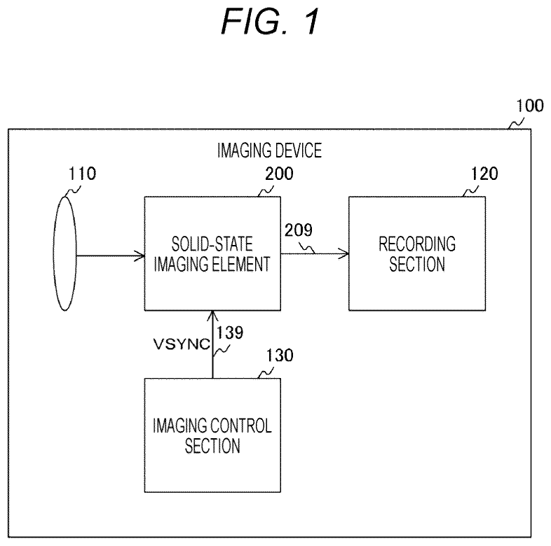

FIG. 1 is a block diagram illustrating a configuration example of an imaging device 100 in a first embodiment of the present technology. The imaging device 100 is a device that captures image data, and includes an imaging lens 110, a solid-state imaging element 200, a recording section 120, and an imaging control section 130. As the imaging device 100, a digital camera or an electronic device (a smartphone, a personal computer, or the like) having an imaging function is assumed.

The solid-state imaging element 200 captures image data under control of the imaging control section 130. The solid-state imaging element 200 supplies the image data to the recording section 120 via a signal line 209.

The imaging lens 110 condenses light and guides the light to the solid-state imaging element 200. The imaging control section 130 controls the solid-state imaging element 200 to capture the image data. For example, the imaging control section 130 supplies an imaging control signal including a vertical synchronization signal VSYNC to the solid-state imaging element 200 via a signal line 139. The recording section 120 records the image data.

Here, the vertical synchronization signal VSYNC is a signal indicating imaging timing, and a periodic signal of a constant frequency (such as 60 Hertz) is used as the vertical synchronization signal VSYNC.

Note that although the imaging device 100 records the image data, the image data may be transmitted to the outside of the imaging device 100. In this case, an external interface for transmitting the image data is further provided. Alternatively, the imaging device 100 may further display the image data. In this case, a display section is further provided.

### [Configuration Example of Solid-State Imaging Element]

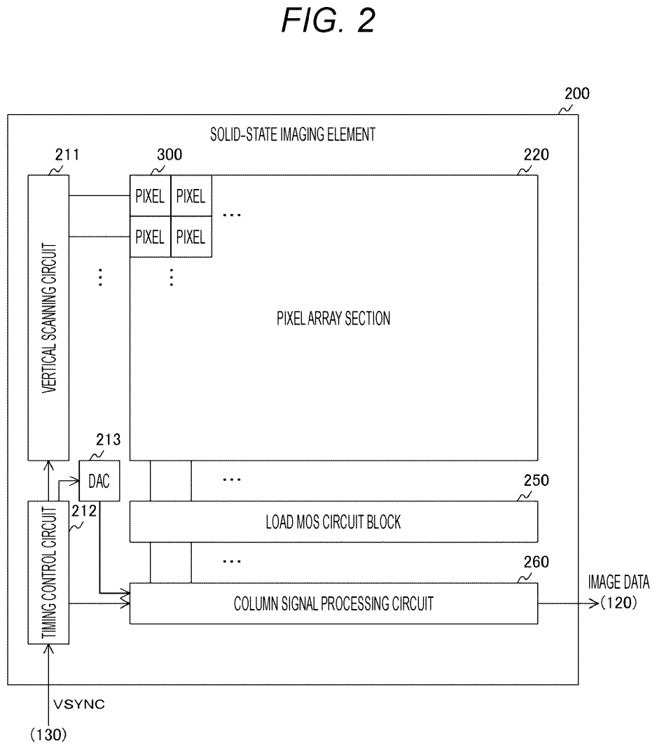

FIG. 2 is a block diagram illustrating a configuration example of the solid-state imaging element 200 according to the first embodiment of the present technology. The solid-state imaging element 200 includes a vertical scanning circuit 211, a pixel array section 220, a timing control circuit 212, a digital to analog converter (DAC) 213, a load MOS circuit block 250, and a column signal processing circuit 260. In the pixel array section 220, a plurality of pixels 300 is arranged in a two-dimensional grid pattern. Furthermore, each circuit in the solid-state imaging element 200 is provided in, for example, a single semiconductor chip.

Hereinafter, a set of the pixels 300 arranged in a horizontal direction will be referred to as “row”, and a set of the pixels 300 arranged in a direction orthogonal to the row will be referred to as “column”.

The timing control circuit 212 controls operation timing of each of the vertical scanning circuit 211, the DAC 213, and the column signal processing circuit 260 in synchronization with the vertical synchronization signal VSYNC from the imaging control section 130.

The DAC 213 generates a sawtooth-shaped ramp signal by digital to analog (DA) conversion. The DAC 213 supplies the generated ramp signal to the column signal processing circuit 260.

The vertical scanning circuit 211 sequentially selects and drives rows to output an analog pixel signal. Each of the pixels 300 photoelectrically converts incident light to generate an analog pixel signal. This pixel 300 supplies the pixel signal to the column signal processing circuit 260 via the load MOS circuit block 250.

In the load MOS circuit block 250, a MOS transistor that supplies a constant current is provided for each column.

The column signal processing circuit 260 performs signal processing such as analog to digital (AD) conversion processing or CDS processing on the pixel signal for each column. The column signal processing circuit 260 supplies the image data including the processed signals to the recording section 120. Note that the column signal processing circuit 260 is an example of a signal processing circuit recited in the claims.

### [Configuration Example of Pixel]

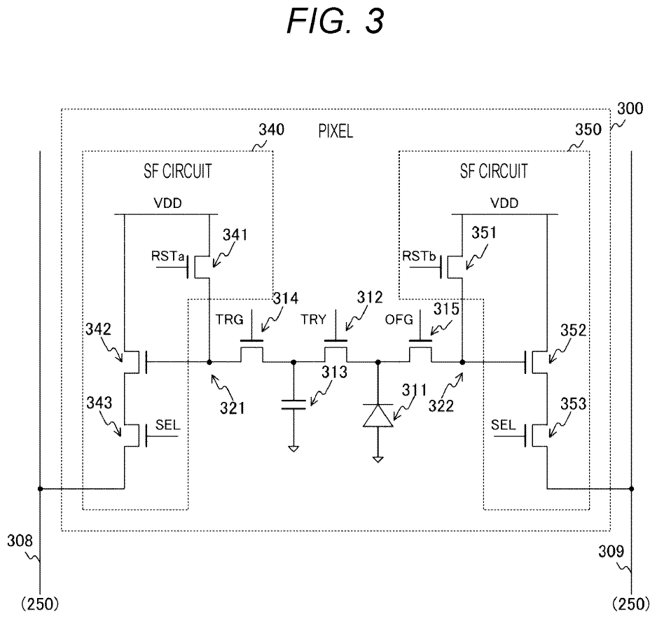

FIG. 3 is a circuit diagram illustrating a configuration example of the pixel 300 according to the first embodiment of the present technology. The pixel 300 includes a photoelectric conversion element 311, transfer transistors 312 and 314, an analog memory 313, an OFG transistor 315, FDs 321 and 322, and source follower circuits 340 and 350. The source follower circuit 340 includes a reset transistor 341, an amplification transistor 342, and a selection transistor 343, and the source follower circuit 350 includes a reset transistor 351, an amplification transistor 352, and a selection transistor 353. Furthermore, vertical signal lines 308 and 309 are wired in the vertical direction for each column.

The photoelectric conversion element 311 generates charges by photoelectric conversion on incident light. The transfer transistor 312 transfers the charges from the photoelectric conversion element 311 to the analog memory 313 in accordance with a transfer signal TRY received from the vertical scanning circuit 211. Note that the transfer transistor 312 is an example of a first transfer transistor recited in the claims.

The analog memory 313 holds the charges. For example, a multi-gate metal-oxide-semiconductor (MOS) transistor is used as the analog memory 313. Note that the analog memory 313 is an example of a charge holding section recited in the claims.

The transfer transistor 314 transfers the charges from the analog memory 313 to the FD 321 in accordance with a transfer signal TRG received from the vertical scanning circuit 211. Note that the transfer transistor 314 is an example of a second transfer transistor recited in the claims.

The OFG transistor 315 opens and closes a path between the photoelectric conversion element 311 and the FD 322 in accordance with a control signal OFG from the vertical scanning circuit 211. Furthermore, the OFG transistor 315 functions as an overflow gate that causes the FD 322 to hold the charge having overflowed from the photoelectric conversion element 311 in the off state.

The FDs 321 and 322 accumulate charges, and generate a voltage according to an amount of charges. Note that the FDs 321 and 322 are examples of first and second floating diffusion layers recited in the claims.

The reset transistor 341 initializes the FD 321 in accordance with a reset signal RSTa received from the vertical scanning circuit 211. The amplification transistor 342 amplifies the voltage of the FD 321. The selection transistor 343 outputs the amplified voltage signal as a pixel signal to the vertical signal line 308 in accordance with a selection signal SEL from the vertical scanning circuit 211. With this circuit configuration, the source follower circuit 340 amplifies and outputs the voltage of the FD 321.

A connection configuration of the reset transistor 351, the amplification transistor 352, and the selection transistor 353 is similar to that of the reset transistor 341, the amplification transistor 342, and the selection transistor 343. However, the reset transistor 351 initializes the FD 322 in accordance with a reset signal RSTb from the vertical scanning circuit 211, and the selection transistor 353 outputs a pixel signal to the vertical signal line 309.

Note that the source follower circuits 340 and 350 are examples of first and second source follower circuits recited in the claims.

At the start of exposure, the vertical scanning circuit 211 brings the OFG transistors 315 and the reset transistors 351 of all the pixels into the on state over the pulse period by the control signal OFG and the reset signal RSTb. Therefore, the photoelectric conversion elements 311 of all the pixels are initialized, and exposure is simultaneously started in all the pixels.

Then, immediately before the end of the exposure, the vertical scanning circuit 211 turns on the reset transistors 341 and the transfer transistors 314 of all the pixels over the pulse period by the reset signal RSTa and the transfer signal TRG. Therefore, the FD 321 and the analog memory 313 are initialized.

At the end of the exposure, the vertical scanning circuit 211 turns on the transfer transistors 312 of all the pixels over the pulse period by a transfer signal TRY. As a result, charge is transferred from the photoelectric conversion element 311 to the analog memory 313, and the exposure ends in all the pixels. In this manner, control that starts and ends exposure simultaneously for all the pixels is called a global shutter method.

After the exposure is completed, the vertical scanning circuit 211 sequentially selects and drives the rows, and each time a row is selected, the column signal processing circuit 260 reads a pixel signal from the row.

The vertical scanning circuit 211 turns on the selection transistors 343 and 353 of the selected row over the readout period by the selection signal SEL. Furthermore, during the readout period, the vertical scanning circuit 211 turns on the reset transistor 341 of the selected row over the pulse period by the reset signal RSTa. Therefore, the FD 321 is initialized. The level of the pixel signal when the FD 321 or 322 is initialized is hereinafter referred to as a “P-phase” or a “reset level”. The column signal processing circuit 260 reads the reset level via the vertical signal line 308. A reset level from the vertical signal line 308 is set to Pa.

Furthermore, in an environment where the illuminance is relatively high, the FD 322 holds the charge having overflowed from the photoelectric conversion element 311 via the OFG transistor 315. The voltage of the pixel signal according to the amount of electric charge accumulated in the FD 321 or the FD 322 is hereinafter referred to as “D-phase” or “signal level”. During reading of the reset level Pa, the column signal processing circuit 260 reads the signal level via the vertical signal line 309. The signal level from the vertical signal line 309 is denoted by Db.

After reading the reset level Pa and the signal level Db, the vertical scanning circuit 211 turns on the transfer transistor 314 of the selected row over the pulse period by the transfer signal TRG. At the same time, the vertical scanning circuit 211 turns on the reset transistor 351 of the selected row over the pulse period by the reset signal RSTb. By these controls, charges are transferred to the FD 321, and the FD 322 is initialized. The column signal processing circuit 260 reads the signal level via the vertical signal line 308 and reads the reset level via the vertical signal line 309. The signal level from the vertical signal line 308 is Da, and the reset level from the vertical signal line 309 is Pb.

As described above, the vertical scanning circuit 211 sequentially selects and drives rows after exposure by the global shutter method. Each time a row is selected, the column signal processing circuit 260 reads the reset level Pa and the signal level Db, and then reads the signal level Da and the reset level Rb.

### [Configuration Example of Column Signal Processing Circuit]

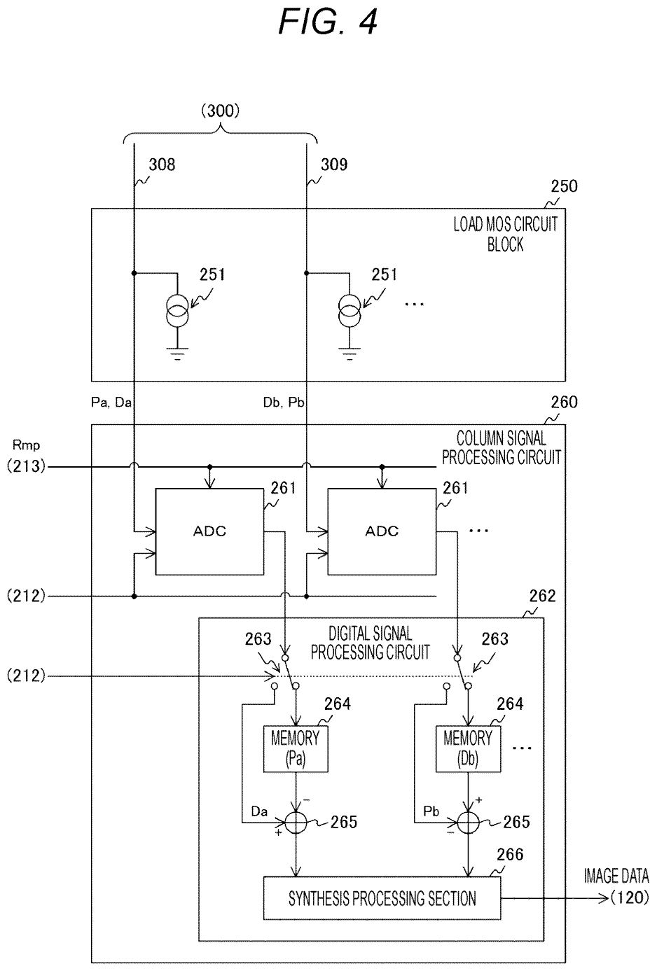

FIG. 4 is a block diagram illustrating a configuration example of the column signal processing circuit 260 according to the first embodiment of the present technology.

In the load MOS circuit block 250, a plurality of load MOS transistors 251 each supplying a constant current id2 is disposed. Each of the load MOS transistors 251 is connected to each of the vertical signal lines. Since two vertical signal lines (308 and 309) are wired for each column, if the number of columns is M (M is an integer), the number of load MOS transistors 251 is 2×M.

The column signal processing circuit 260 includes a plurality of ADCs 261 and a digital signal processing circuit 262. Each of the ADCs 261 is connected to each of the vertical signal lines. Since two vertical signal lines are wired for each column, the number of ADCs 261 is 2×M.

The digital signal processing circuit 262 includes a plurality of selectors 263, a plurality of memories 264, a plurality of subtractors 265, and a synthesis processing section 266. The selector 263, the memory 264, and the subtractor 265 are disposed for each ADC 261. Since the number of the ADCs 261 is 2×M, the number of the selectors 263, the number of the memories 264, and the number of the subtractors 265 are also 2 ×M.

The ADC 261 converts an analog pixel signal from the corresponding vertical signal line into a digital signal using a ramp signal Rmp from the DAC 213. The ADC 261 supplies the digital signal to the digital signal processing circuit 262. For example, a single-slope ADC including a comparator and a counter is disposed as the ADC 261.

The vertical signal line 308 outputs the signal level Da next to the reset level Pa of the pixel signal, while the vertical signal line 309 outputs the reset level Pb next to the signal level Db of the pixel signal. Each of the ADCs 261 sequentially performs AD conversion on the reset level and the signal level, and supplies the result of the AD conversion to the corresponding selector 263.

The selector 263 switches an output destination of the digital signal (reset level or signal level) from the ADC 261 under the control of the timing control circuit 212. The selector 263 corresponding to the vertical signal line 308 causes the memory 264 to hold the reset level Pa and supplies the signal level Da to the subtractor 265. On the other hand, the selector 263 corresponding to the vertical signal line 309 causes the memory 264 to hold the signal level Db and supplies the reset level Pb to the subtractor 265.

The subtractor 265 obtains a difference between a signal (reset level or signal level) held in the corresponding memory 264 and a signal from the corresponding selector 263. The subtractor 265 corresponding to the vertical signal line 308 subtracts the reset level Pa held in the memory 264 from the signal level Da from the selector 263, and supplies the result to the synthesis processing section 266 as a net signal level SIGa. On the other hand, the subtractor 265 corresponding to the vertical signal line 309 subtracts the reset level Pb from the selector 263 from the signal level Db held in the memory 264, and supplies the result to the synthesis processing section 266 as a net signal level SIGb. As described above, the process of obtaining the difference between the reset level and the signal level corresponds to the CDS processing.

The synthesis processing section 266 performs synthesis processing of adding the signal levels SIGa and SIGb for each column. The synthesis processing section 266 performs various types of signal processing on the image data in which the synthesized signals are arranged, and supplies the processed image data to the recording section 120.

The signal level SIGa is a level corresponding to the amount of charge transferred to the analog memory 313. The signal level SIGb is a level corresponding to the amount of charges having overflowed from the photoelectric conversion element 311, and is generated at high illuminance. Therefore, the dynamic range of the image data can be expanded by adding these signal levels.

Here, a comparative example in which a plurality of pieces of image data is captured with different exposure times and synthesized is assumed. The dynamic range can also be expanded by the method of the comparative example. However, in the comparative example, it is necessary to capture a plurality of images each time of synthesis, and there is a possibility that the power consumption increases and the frame rate decreases as compared with a case where no synthesis is performed.

On the other hand, in the configuration in which the processing of synthesizing SIGb at the time of overflow with the signal level SIGa is performed for each pixel, the number of times of imaging is only one, and the power consumption and the frame rate can be improved as compared with the comparative example.

### [Operation Example of Solid-State Imaging Element]

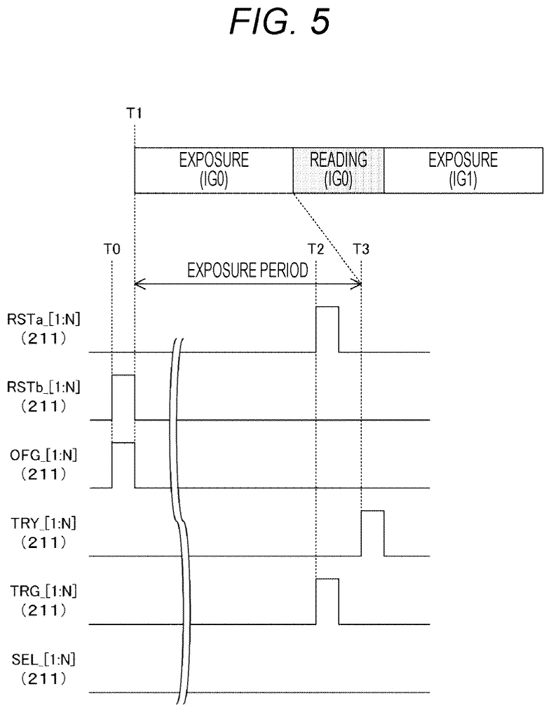

FIG. 5 is a timing chart illustrating an example of exposure control of the solid-state imaging element 200 according to the first embodiment of the present technology. The vertical scanning circuit 211 supplies the high-level reset signal RSTb and the control signal OFG to all rows (that is, all pixels) in a period from timing T0 immediately before the exposure start to timing T1 of the exposure start. Therefore, the photoelectric conversion elements 311 of all the pixels are initialized, and exposure is simultaneously started in all the pixels.

Here, when n is an integer from 1 to N, RSTa_[n], RSTb_[n], OFG_[n], TRG_[n], and SEL_[n] indicate signals to the nth row.

Then, the vertical scanning circuit 211 supplies the high-level reset signal RSTa and the high-level transfer signal TRG to all the pixels over the pulse period from timing T2 immediately before the start of the exposure. As a result, the analog memory 313 is reset in all the pixels.

The vertical scanning circuit 211 supplies the high-level transfer signal TRY to all the pixels over the pulse period from timing T3 of the end of the exposure. Therefore, charges are transferred to the analog memory 313 in all the pixels, and exposure is simultaneously ended in all the pixels.

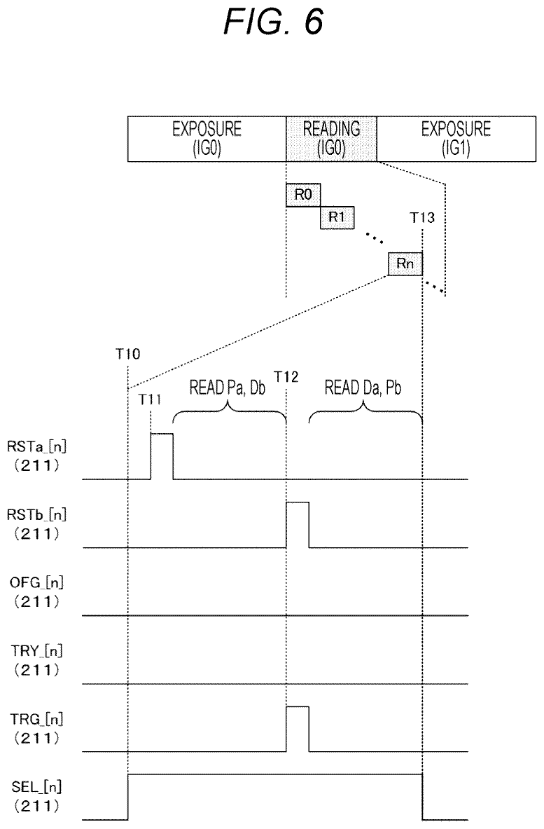

FIG. 6 is a timing chart illustrating an example of a read operation of the solid-state imaging element 200 according to the first embodiment of the present technology. The vertical scanning circuit 211 sequentially selects and drives the rows within the readout period after the end of the exposure, and causes the column signal processing circuit 260 to execute readout. In the drawing, Rn indicates a readout period of the nth row. After reading all the rows, the next exposure is started. In the drawing, IG0 is image data generated by the first exposure, and IG1 is image data generated by the second exposure.

During a readout period of the nth row from timing T10 to timing T13, the vertical scanning circuit 211 supplies the high-level selection signal SEL to the nth row. The vertical scanning circuit 211 supplies the high-level reset signal RSTa to the nth row over the pulse period from timing T11 in the readout period. As a result, the FD 321 is initialized, and the reset level Pa is read. Furthermore, in parallel with the reading of the reset level Pa, the signal level Db at the time of overflow is read.

Then, the vertical scanning circuit 211 supplies the high-level reset signal RSTb and the high-level transfer signal TRG to the nth row over the pulse period from timing T12. Therefore, the electric charge is transferred to the FD 321, and the signal level Da is read. Furthermore, the FD 322 is initialized, and the reset level Pb is read.

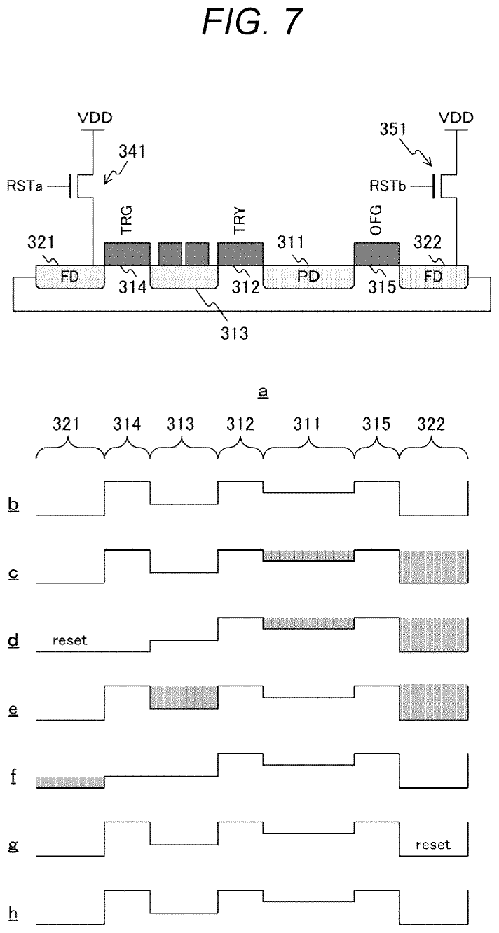

FIG. 7 is an example of a potential diagram of the pixel 300 according to the first embodiment of the present technology. In the drawing, a illustrates a cross-sectional view of the pixel 300.

In the drawing, b is a potential diagram illustrating a state of the pixel 300 at the start of exposure. As illustrated in b of the drawing, the photoelectric conversion element 311 is initialized.

c of the drawing is a potential diagram illustrating a state of the pixel 300 being exposed. As illustrated in c of the drawing, a charge is generated in the photoelectric conversion element 311, and the charge having overflowed from the photoelectric conversion element 311 is accumulated in the FD 322.

In the drawing, d is a potential diagram illustrating a state of the pixel 300 immediately before the end of exposure. As illustrated in d of the drawing, the vertical scanning circuit 211 turns on the transfer transistor 314 immediately before transfer, and initializes the analog memory 313.

In the drawing, e is a potential diagram illustrating a state of the pixel 300 immediately after the end of exposure. As illustrated in e of the drawing, a charge is transferred from the photoelectric conversion element 311 to the analog memory 313. Then, the vertical scanning circuit 211 initializes the FD 321. Next, reading of the reset level Pa and the signal level Db at the time of overflow is executed.

f in the drawing is a potential diagram illustrating a state of the pixel 300 at the time of reading the signal level Da. As illustrated in f of the drawing, the vertical scanning circuit 211 transfers a charge from the analog memory 313 to the FD 321. Then, the signal level Da is read.

In the drawing, g is a potential diagram illustrating a state of the pixel 300 at the time of initialization of the FD 322. As illustrated in g of the drawing, the FD 322 is initialized.

In the drawing, h is a potential diagram illustrating the state of the pixel 300 at the time of reading the signal level Pb. In f, g, and h in the drawing, for convenience of description, the signal level Da and the signal level Pb are described to be read one by one, but in practice, these can be read simultaneously.

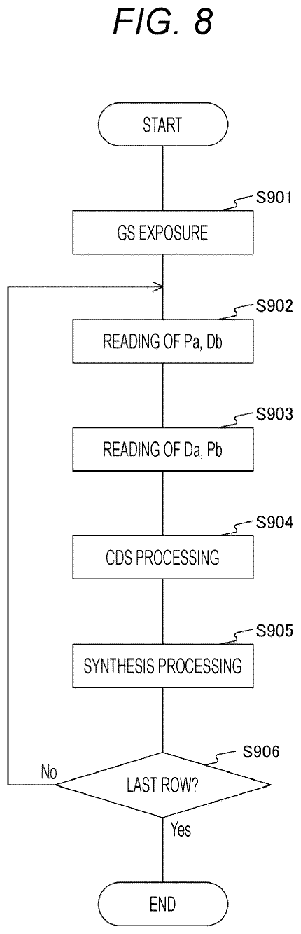

FIG. 8 is a flowchart illustrating an example of an operation of the solid-state imaging element 200 according to the first embodiment of the present technology. This operation starts, for example, when a predetermined application for capturing image data is executed.

The solid-state imaging element 200 performs exposure by the global shutter method (step S901). Then, the solid-state imaging element 200 selects a row and reads the reset level Pa of the row and the signal level Db at the time of overflow (step S902). Next, the solid-state imaging element 200 reads the signal level Da of the selected row and the reset level Pb on the overflow side (step S903).

The solid-state imaging element 200 performs CDS processing of obtaining each of the difference between the reset level Pa and the signal level Da and the difference between the reset level Pb and the signal level Db (step S904). The solid-state imaging element 200 performs synthesis processing of adding the CDS processed signals (step S905), and determines whether or not the selected row is the last row (step S906).

In a case where a row that has been selected is not the last row (step S906: No), the solid-state imaging element 200 repeatedly executes step S902 and subsequent steps. On the other hand, in a case where the row that has been selected is the last row (step S906: Yes), the solid-state imaging element 200 ends the processing for imaging.

Note that in a case where a plurality of pieces of image data is continuously captured, the solid-state imaging element 200 repeatedly executes processing of steps S901 to S906 in synchronization with the vertical synchronization signal.

As described above, according to the first embodiment of the present technology, since the OFG transistor 315 causes the FD 322 to hold the charge having overflowed from the photoelectric conversion element 311, it is possible to expand the dynamic range while suppressing the number of captured images and power consumption.

### 2. Second Embodiment

In the first embodiment described above, the source follower circuits 340 and 350 are provided for each pixel, but in this configuration, the two vertical signal lines and the two ADCs are required for each column. A solid-state imaging element 200 in a second embodiment is different from that in the first embodiment in that the source follower circuit 340 and the ADCs are eliminated.

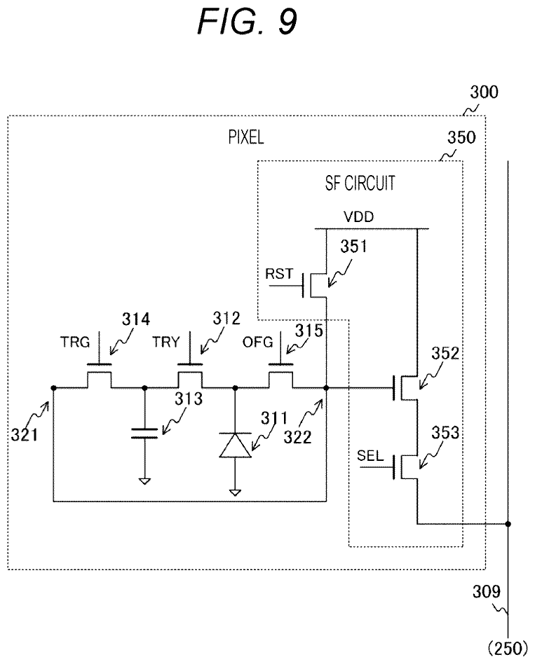

FIG. 9 is a circuit diagram illustrating a configuration example of a pixel 300 according to the second embodiment of the present technology. The pixel 300 of the second embodiment is different from that of the first embodiment in that the source follower circuit 340 is not provided. Furthermore, the vertical signal line 308 is not wired, and only one vertical signal line 309 is wired for each column. Furthermore, an FD 321 is connected to an FD 322, and a reset signal RST from a vertical scanning circuit 211 is input to a gate of a reset transistor 351.

Furthermore, in the second embodiment, unlike the first embodiment, a signal level Db, a reset level (P-phase), and a signal level Da are read sequentially for each row.

Furthermore, in a column signal processing circuit 260, one ADC 261 is disposed for each column. Furthermore, the column signal processing circuit 260 holds the signal level Db and the reset level (P-phase), and obtains a difference therebetween as SIGb. Next, the column signal processing circuit 260 obtains a difference between the signal level Da and the P-phase as SIGa, and performs synthesis processing of adding SIGa and SIGb.

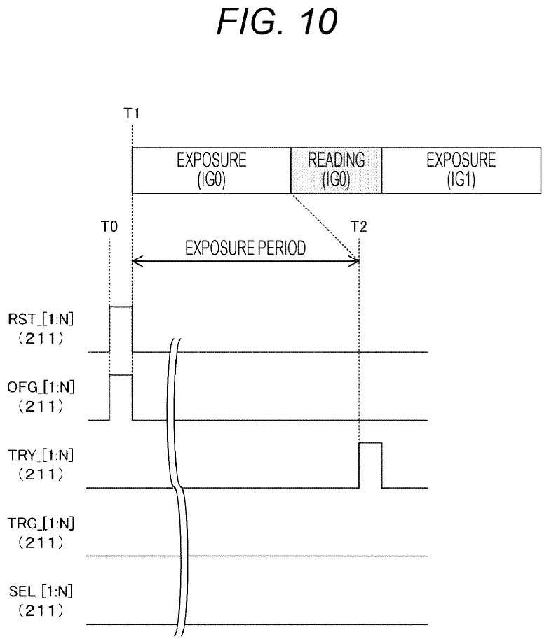

FIG. 10 is a timing chart illustrating an example of exposure control of the solid-state imaging element 200 according to the second embodiment of the present technology. The vertical scanning circuit 211 supplies the high-level reset signal RST and the high-level control signal OFG to all the pixels from timing T0 immediately before the exposure start to timing T1 of the exposure start. Therefore, the photoelectric conversion elements 311 of all the pixels are initialized, and exposure is simultaneously started in all the pixels.

Then, the vertical scanning circuit 211 supplies the high-level transfer signal TRY to all the pixels over the pulse period from timing T2 of the end of the exposure. Therefore, charges are transferred to the analog memory 313 in all the pixels, and exposure is simultaneously ended in all the pixels. Note that unlike the first embodiment, initialization of the FD 321 immediately before exposure is not executed.

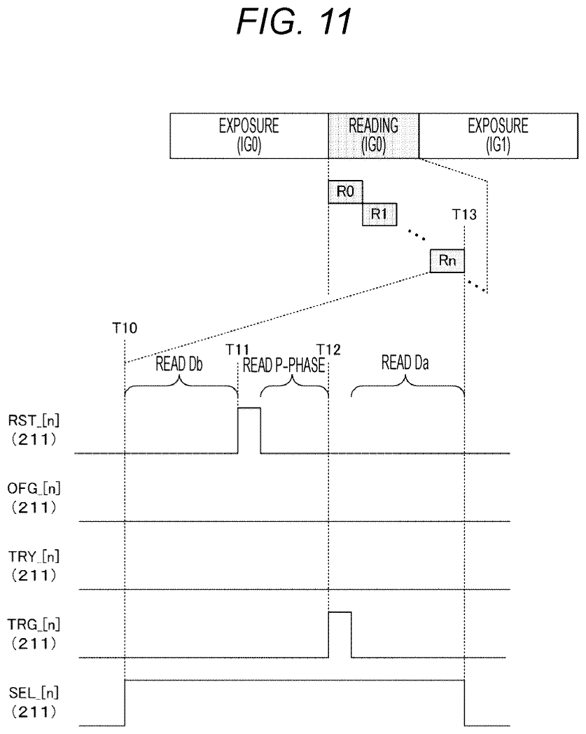

FIG. 11 is a timing chart illustrating an example of a read operation of the solid-state imaging element 200 according to the second embodiment of the present technology.

During a readout period of the nth row from timing T10 to timing T13, the vertical scanning circuit 211 supplies the high-level selection signal SEL to the nth row. The signal level Db at the time of overflow is read over a predetermined period from the timing T10.

The vertical scanning circuit 211 supplies the high-level reset signal RST to the nth row over the pulse period from timing T11 after reading of the signal level Db. Therefore, the FD 321 and the FD 322 are initialized, and the reset level (P-phase) is read.

Then, the vertical scanning circuit 211 supplies the high-level transfer signal TRG to the nth row er the pulse period from timing T12. Therefore, the charge is transferred to the FD 211, and the signal level Da is read.

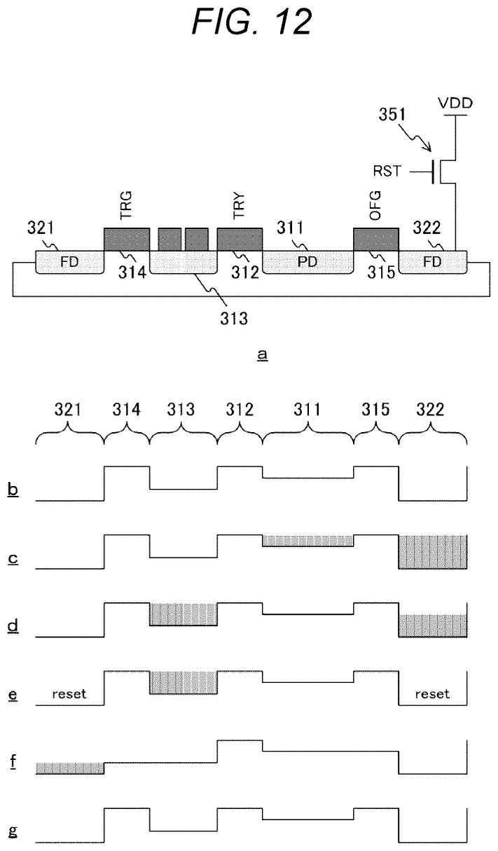

FIG. 12 is an example of a potential diagram of the pixel 300 according to the second embodiment of the present technology. In the drawing, a illustrates a cross-sectional view of the pixel 300.

In the drawing, b is a potential diagram illustrating a state of the pixel 300 at the start of exposure. As illustrated in b of the drawing, the photoelectric conversion element 311 is initialized.

c of the drawing is a potential diagram illustrating a state of the pixel 300 being exposed. As illustrated in c of the drawing, a charge is generated in the photoelectric conversion element 311, and the charge having overflowed from the photoelectric conversion element 311 is accumulated in the FD 322.

In the drawing, d is a potential diagram illustrating a state of the pixel 300 immediately after the end of exposure. As illustrated in d of the drawing, a charge is transferred from the photoelectric conversion element 311 to the analog memory 313. Then, reading of the signal level Db at the time of overflow is executed.

In the drawing, e is a potential diagram illustrating a state of the pixel 300 at the time of initialization of the FDs 321 and 322. At this time, the reset level is read.

f in the drawing is a potential diagram illustrating a state of the pixel 300 at the time of reading the signal level Da. As illustrated in f of the drawing, the vertical scanning circuit 211 transfers a charge from the analog memory 313 to the FD 321. Then, reading of the signal level Da is executed.

In the drawing, g is a potential diagram illustrating a state of the pixel 300 at the start of the next exposure. As exemplified in g of the drawing, the photoelectric conversion element 311 is initialized again.

As described above, according to the second embodiment of the present technology, since the source follower circuit 340 is eliminated, the number of pixels can be easily increased.

### 3. Third Embodiment

In the second embodiment described above, the overflowing charge is held in the FD 322, but in this configuration, the photoelectric conversion element 311 cannot be initialized via the FD 322 during reading. In other words, the pipeline operation of starting the next exposure during the reading cannot be realized. A solid-state imaging element 200 of a third embodiment is different from that of the second embodiment in that an FD and a transistor are added, and the pipeline operation is realized.

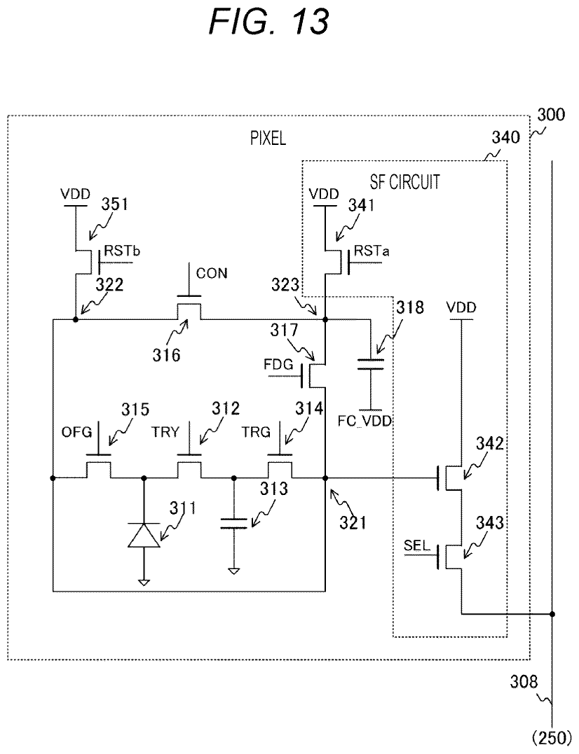

FIG. 13 is a circuit diagram illustrating a configuration example of a pixel 300 according to the third embodiment of the present technology. The pixel 300 of the third embodiment is different from that of the second embodiment in that not the source follower circuit 340 but the source follower circuit 350 on the overflow side is eliminated. However, the reset transistor 351 is not eliminated. Furthermore, the pixel 300 of the third embodiment differs from that of the second embodiment in further including a connection transistor 316, an FDG transistor 317, a metal-insulator-metal (MIM) capacitor 318, and an FD 323.

The connection transistor 316 opens and closes a path between an FD 322 and the FD 323 in accordance with a control signal CON from a vertical scanning circuit 211. The FDG transistor 317 opens and closes a path between the FD 321 and the FD 323 in accordance with a control signal FDG from the vertical scanning circuit 211. The MIM capacitor 318 is connected to the FD 323. Note that the FDG transistor 317 is an example of a conversion efficiency control transistor recited in the claims. Furthermore, the FD 323 is an example of a third floating diffusion layer recited in the claims.

Here, the capacitance value of the FD 321 is assumed to be substantially the same as the FD 322, for example. Furthermore, from the viewpoint of reducing noise, the capacitance value of the FD 323 is preferably 10 times or more of the FD 321 (or the FD 322).

Furthermore, in the third embodiment, similarly to the second embodiment, a signal level Db, a set level (P-phase), and a signal level Da are read sequentially for each row. Then, within the readout period, the vertical scanning circuit 211 can start the next exposure. This is because the overflowing charge is transferred from the FD 322 to the MIM capacitor 318 at the end of the exposure.

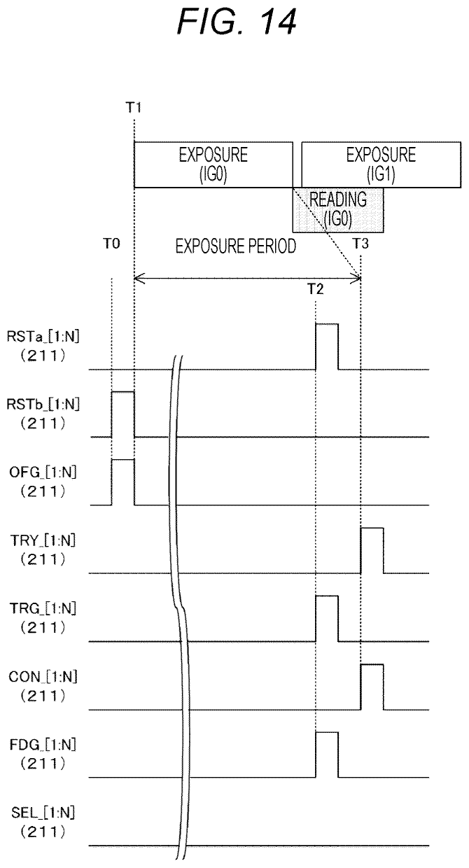

FIG. 14 is a timing chart illustrating an example of exposure control of the solid-state imaging element 200 according to the third embodiment of the present technology. The vertical scanning circuit 211 supplies the high-level reset signal RSTb and the high-level control signal OFG to all the pixels from timing T0 immediately before the exposure start to timing T1 of the exposure start. Therefore, the photoelectric conversion elements 311 of all the pixels are initialized, and exposure is simultaneously started in all the pixels.

Then, immediately before the end of the exposure, the vertical scanning circuit 211 turns on the reset transistors 341, the transfer transistors 314, and the FDG transistors 317 of all the pixels over the pulse period by the reset signal RSTa, the transfer signal TRG, and the control signal FDG. Therefore, the FD 321, the FD 323, and the analog memory 313 are initialized.

The vertical scanning circuit 211 supplies the high-level transfer signal TRY and the control signal CON to all the pixels over the pulse period from timing T3 of the end of the exposure. Therefore, charges are transferred to the analog memory 313 in all the pixels, and charges are transferred from the FD 322 to the MIM capacitor 318, and the exposure ends simultaneously in all the pixels.

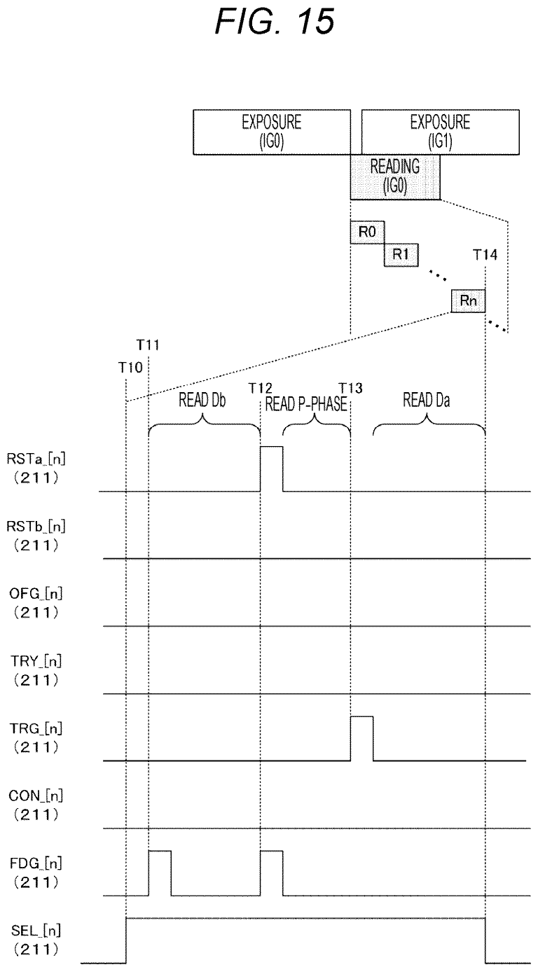

FIG. 15 is a timing chart illustrating an example of a read operation of the solid-state imaging element 200 according to the third embodiment of the present technology.

During a readout period of the nth row from timing T10 to timing T14, the vertical scanning circuit 211 supplies the high-level selection signal SEL to the nth row. The vertical scanning circuit 211 supplies the high-level control signal FDG to the nth row over the pulse period from timing T11 immediately after that. As a result, charges are transferred from the FD 323 to the FD 321, and the signal level Db at the time of overflow is read.

The vertical scanning circuit 211 supplies the high-level reset signal RSTa and the high-level control signal FDG to the nth row over the pulse period from timing T12 after reading of the signal level Db. Therefore, the FDs 321 and 323 are initialized, and the reset level (P-phase) is read.

Then, the vertical scanning circuit 211 supplies the high-level transfer signal TRG to the nth row over the pulse period from timing T13. Therefore, the electric charge is transferred to the FD 321, and the signal level Da is read. At this time, the high-level control signal FDG is supplied as necessary.

Furthermore, since the overflowing charge has been transferred from the FD 322 to the MIM capacitor 318 at the end of the exposure, the vertical scanning circuit 211 can start the next exposure during reading of each row. As a result, it is possible to realize a pipeline operation of starting the next exposure during reading.

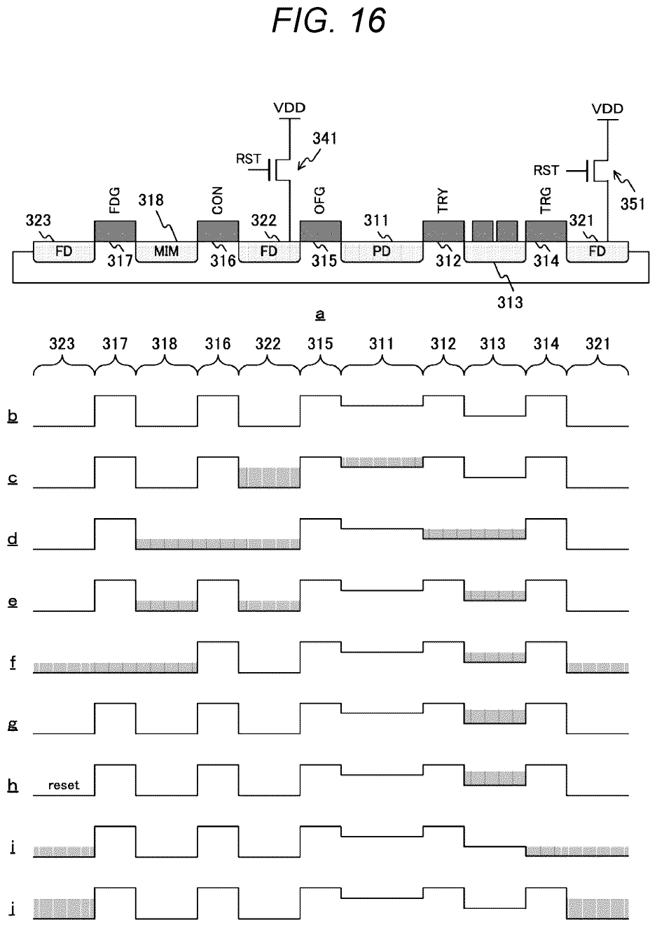

FIG. 16 is an example of a potential diagram of the pixel 300 according to the third embodiment of the present technology. In the drawing, a illustrates a cross-sectional view of the pixel 300.

In the drawing, b is a potential diagram illustrating a state of the pixel 300 at the start of exposure. As illustrated in b of the drawing, the photoelectric conversion element 311 is initialized.

c of the drawing is a potential diagram illustrating a state of the pixel 300 being exposed. As illustrated in c of the drawing, a charge is generated in the photoelectric conversion element 311, and the charge having overflowed from the photoelectric conversion element 311 is accumulated in the FD 322.

In the drawing, d is a potential diagram illustrating a state of the pixel 300 immediately after the end of exposure. As illustrated in d of the drawing, the vertical scanning circuit 211 turns on the transfer transistor 312 and transfers the charge from the photoelectric conversion element 311 to the analog memory 313. Furthermore, the vertical scanning circuit 211 turns on the connection transistor 316 to transfer charges from the FD 322 to the MIM capacitor 318.

Then, as illustrated in e of the drawing, the vertical scanning circuit 211 turns off the transfer transistor 312 and the connection transistor 316 after the pulse period has elapsed. At this time point, since the overflowed charge is transferred to the MIM capacitor 318, the vertical scanning circuit 211 can start the next exposure.

In the drawing, f is a potential diagram illustrating a state of the pixel 300 at the time of reading the signal level Db. As illustrated in f of the drawing, the vertical scanning circuit 211 turns on the FDG transistor 317 and transfers a charge from the MIM capacitor 318 to the FD 321. Then, reading of the signal level Db is executed.

Then, as illustrated in g of the drawing, the vertical scanning circuit 211 turns off the FDG transistor.

In the drawing, h is a potential diagram illustrating a state of the pixel 300 at the time of reading the reset level. As illustrated in h of the drawing, the vertical scanning circuit 211 initializes the FD 321 and the FD 323. Then, reading of the reset level is executed.

In the drawing, i is a potential diagram illustrating a state of the pixel 300 at the time of charge transfer. As illustrated in i of the drawing, the vertical scanning circuit 211 turns on the transfer transistor 314 to transfer the charge from the analog memory 313 to the FD 321.

Next, as exemplified in j of the drawing, the vertical scanning circuit 211 turns off the transfer transistor 314 after the pulse period has elapsed. Then, reading of the signal level Da is executed.

As described above, according to the third embodiment of the present technology, the vertical scanning circuit 211 controls the connection transistor 316 at the end of exposure and transfers the overflowing charge from the FD 322 to the MIM capacitor 318, so that the pipeline operation can be realized.

### 4. Fourth Embodiment

In the third embodiment described above, the FD 321 and the source follower circuit 340 are disposed for each pixel, but in this configuration, it is difficult to reduce the circuit scale per pixel. A solid-state imaging element 200 in a fourth embodiment is different from that in the third embodiment in that a plurality of pixels shares an FD 321 and a source follower circuit 340.

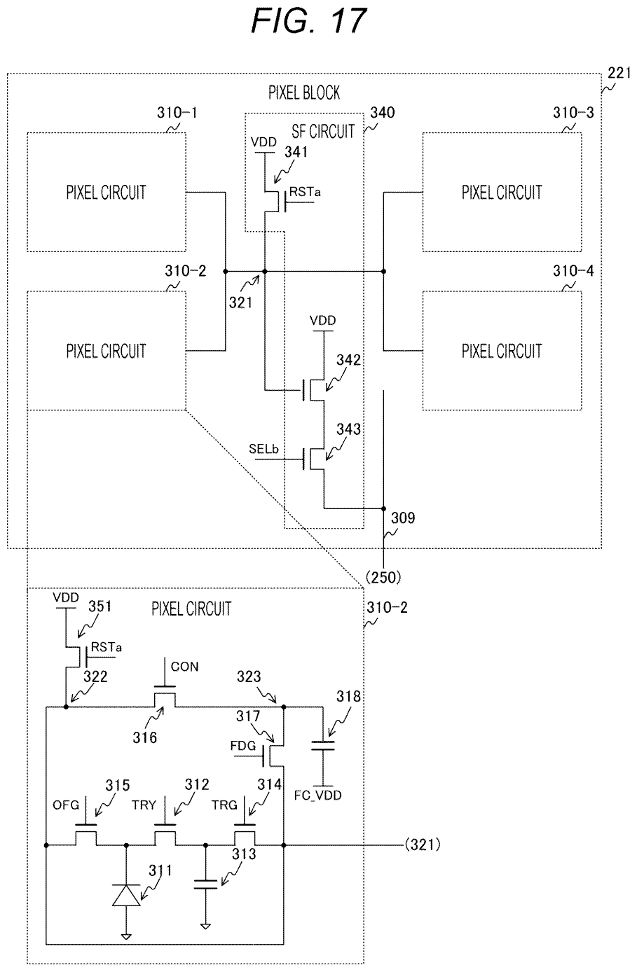

FIG. 17 is a circuit diagram illustrating a configuration example of a pixel block 221 in the fourth embodiment of the present technology. In the fourth embodiment, a pixel array section 220 is divided into a plurality of pixel blocks 221. In each of the pixel blocks 221, a plurality of pixels sharing the FD 321 and the source follower circuit 340 is arranged. For example, four pixels of 2 rows×2 columns are arranged in the pixel block 221.

For example, the pixel circuits 310-1, 310-2, 310-3, and 310-4, the FD 321, and the source follower circuit 340 are disposed in the pixel block 221.

In the pixel circuit 310-2, a photoelectric conversion element 311, transfer transistors 312 and 314, an analog memory 313, an OFG transistor 315, and an FD 322 are disposed. In the pixel circuit 310-2, a reset transistor 351, a connection transistor 316, an FDG transistor 317, a MIM capacitor 318, and an FD 323 are further disposed. These connection configurations are similar to the connection configurations of the third embodiment. The circuit configuration of the pixel circuits 310-1, 310-3, and 310-4 is similar to that of the pixel circuit 310-2.

Furthermore, the pixel circuits 310-1, 310-2, 310-3, and 310-4 share the FD 321 and the source follower circuit 340. By such sharing, the circuit scale per pixel can be reduced as compared with the third embodiment in which the FD 321 and the source follower circuit 340 are disposed for each pixel.

Note that the number of pixels sharing the FD 321 or the like is not limited to four pixels, and may be two pixels, eight pixels or the like. Furthermore, the sharing structure of the fourth embodiment can also be applied to the first embodiment and the second embodiment.

As described above, according to the fourth embodiment of the present technology, since the plurality of pixels shares the FD 321 or the like, a circuit scale per pixel can be reduced as compared with the third embodiment.

### 5. Fifth Embodiment

In the first embodiment described above, the overflowing charge is held in the FD 322, but in this configuration, the linearity is deteriorated due to the influence of fitted pattern noise (FPN) due to the dark current of the FD 321. A solid-state imaging element 200 according to a fifth embodiment differs from that of the first embodiment in that overflowing charges are held in the analog memory 313.

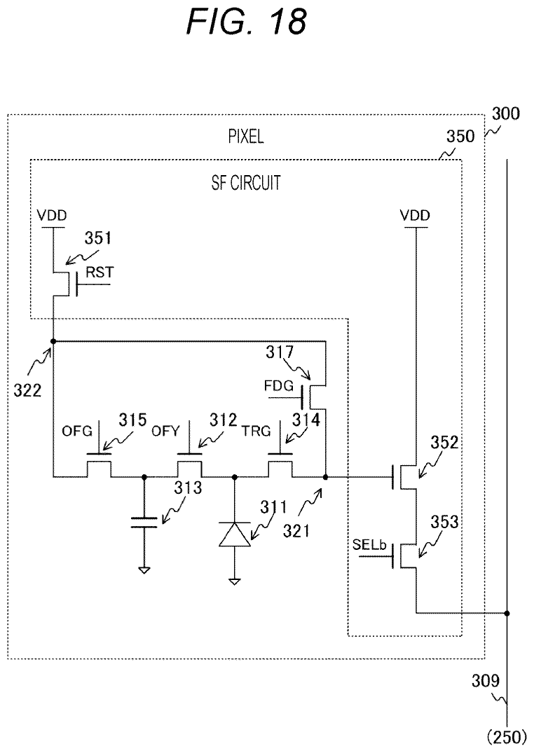

FIG. 18 is a circuit diagram illustrating a configuration example of a pixel 300 according to the fifth embodiment of the present technology. The pixel 300 of the fifth embodiment is different from that of the first embodiment in that the source follower circuit 340 is not provided and an FDG transistor 317 is further disposed.

Furthermore, the transfer transistor 314 transfers the charge from the photoelectric conversion element 311 to the FD 321 in accordance with a transfer signal TRG. The transfer transistor 312 transfers the charge having overflowed from the photoelectric conversion element 311 to the analog memory 313 according to a control signal OFY. The OFG transistor 315 transfers the overflowing charge from the analog memory 313 to the FD 322 and causes the FD 322 to hold the charge. The FDG transistor 317 opens and closes a path between the FD 321 and the FD 322 in accordance with a control signal FDG. The FD 321 is connected to a gate of the amplification transistor 352.

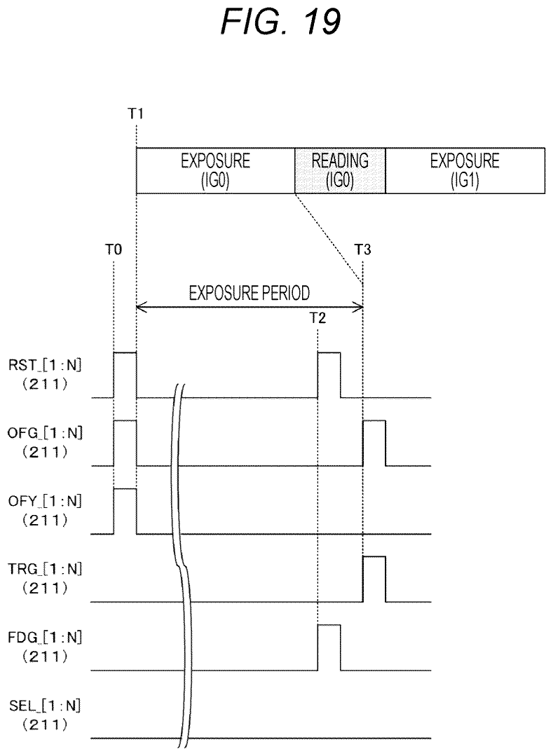

FIG. 19 is a timing chart illustrating an example of exposure control of a solid-state imaging element 200 according to the fifth embodiment of the present technology. During a period from the timing T0 immediately before the exposure start to the timing T1 of the exposure start, a vertical scanning circuit 211 supplies a high-level reset signal RST, a control signal OFG, and a control signal OFY to all the pixels. Therefore, the photoelectric conversion elements 311 of all the pixels are initialized, and exposure is simultaneously started in all the pixels.

Then, the vertical scanning circuit 211 supplies the high-level reset signal RSTa and the high-level control signal FDG to all the pixels over the pulse period from timing T2 immediately before the end of the exposure period. Therefore, the FDs 321 and 322 of all the pixels are initialized.

The vertical scanning circuit 211 supplies the high-level transfer signal TRG and the high-level control signal OFG to all the pixels over the pulse period from timing T3 of the end of the exposure. Therefore, the charge is transferred from the photoelectric conversion element 311 to the FD 321, and the overflowing charge is transferred from the analog memory 313 to the FD 322, and the exposure ends in all the pixels.

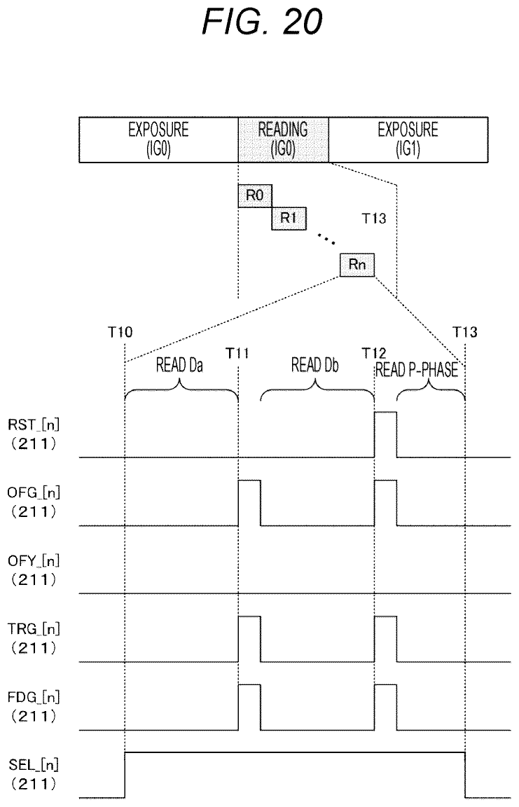

FIG. 20 is a timing chart illustrating an example of a read operation of the solid-state imaging element 200 according to the fifth embodiment of the present technology.

During a readout period of the nth row from timing T10 to timing T13, the vertical scanning circuit 211 supplies the high-level selection signal SEL to the nth row. The signal level Da is read out over a predetermined period from timing T10.

The vertical scanning circuit 211 supplies the high-level transfer signal TRG, the high-level control signal OFG, and the high-level control signal FDG to the nth row over the pulse period from timing T11 after reading the signal level Da. Therefore, charges are transferred from the FD 322 to the FD 321, and the signal level Db at the time of overflow is read.

Then, the vertical scanning circuit 211 supplies the high-level reset signal RST, the high-level transfer signal TRG, the high-level control signal OFG, and the high-level control signal FDG to the nth row over the pulse period from timing T12 after reading the signal level Db. Therefore, the FD 321 and the FD 322 are initialized, and the reset level (P-phase) is read.

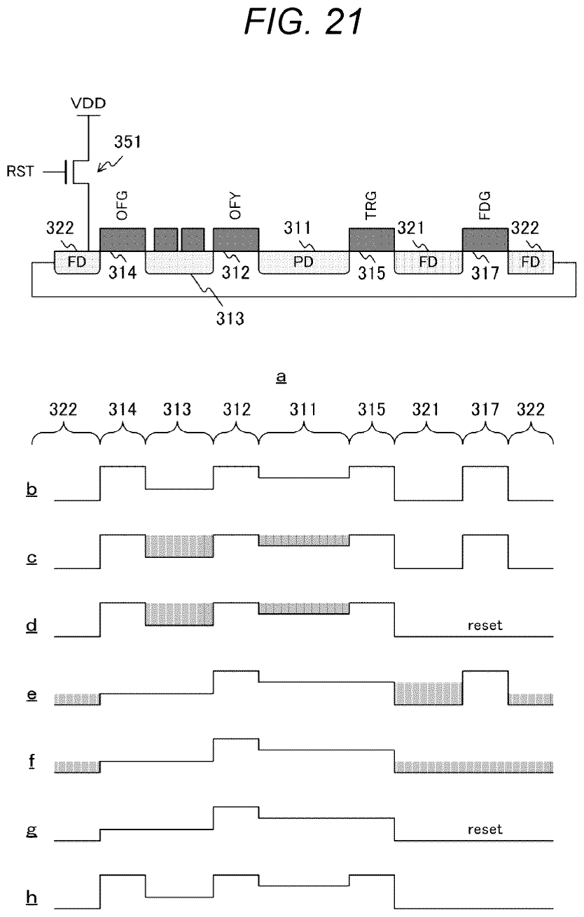

FIG. 21 is an example of a potential diagram of the pixel 300 according to the fifth embodiment of the present technology. In the drawing, a illustrates a cross-sectional view of the pixel 300.

In the drawing, b is a potential diagram illustrating a state of the pixel 300 at the start of exposure. As illustrated in b of the drawing, the photoelectric conversion element 311 is initialized.

c of the drawing is a potential diagram illustrating a state of the pixel 300 being exposed. As illustrated in c of the drawing, a charge is generated in the photoelectric conversion element 311, and the charge having overflowed from the photoelectric conversion element 311 is accumulated in the analog memory 313.

In the drawing, d is a potential diagram illustrating a state of the pixel 300 immediately before the end of exposure. As illustrated in d of the drawing, the vertical scanning circuit 211 turns on the reset transistor 351 and the FDG transistor 317, and initializes the FD 321 and the FD 322.

In the drawing, e is a potential diagram illustrating a state of the pixel 300 at the end of exposure. As illustrated in e of the drawing, the vertical scanning circuit 211 turns on the transfer signal TRG and the control signal OFG. Therefore, the charges are transferred from the photoelectric conversion element 311 to the FD 321, and the overflowing charges are transferred from the analog memory 313 to the FD 322. Then, reading of the signal level Da is executed.

In the drawing, f is a potential diagram illustrating a state of the pixel 300 at the time of reading the signal level Db. As illustrated in f of the drawing, the vertical scanning circuit 211 turns on the transfer signal TRG, the control signal OFG, and the control signal FDG. Therefore, charges are transferred from the FD 322 to the FD 321, and reading of the signal level Db is executed.

In the drawing, g is a potential diagram illustrating a state of the pixel 300 at the time of reading the reset level. As illustrated in g of the drawing, the vertical scanning circuit 211 brings the reset transistor 351, the transfer transistor 314, the OFG transistor 315, and the FDG transistor 317 into the on state. Therefore, the FD 321 and the FD 322 are initialized, and reading of the reset level is executed.

In the drawing, h is a potential diagram illustrating a state of the pixel 300 at the start of the next exposure. As illustrated in f of the drawing, the photoelectric conversion element 311 is initialized again.

As illustrated in the drawing, by causing the analog memory 313 to hold the charge having overflowed from the photoelectric conversion element 311, deterioration of linearity can be suppressed.

As described above, according to the fifth embodiment of the present technology, since the charges having overflowed from the photoelectric conversion element 311 are held in the analog memory 313, deterioration of linearity can be suppressed as compared with a case where the overflowing charges are held in the FD 322.

### 6. Sixth Embodiment

In the first embodiment described above, charges are held in the analog memory 313 in the preceding stage of the FD 321. As described above, the method of holding the charge before charge-voltage conversion in the analog memory 313 as it is called a charge domain method. In this charge domain method, it is difficult to achieve both miniaturization and an increase in saturation capacity in order to secure the area of the analog memory 313. A solid-state imaging element 200 of a sixth embodiment is different from that of the first embodiment in that a sample hold circuit 400 is added.

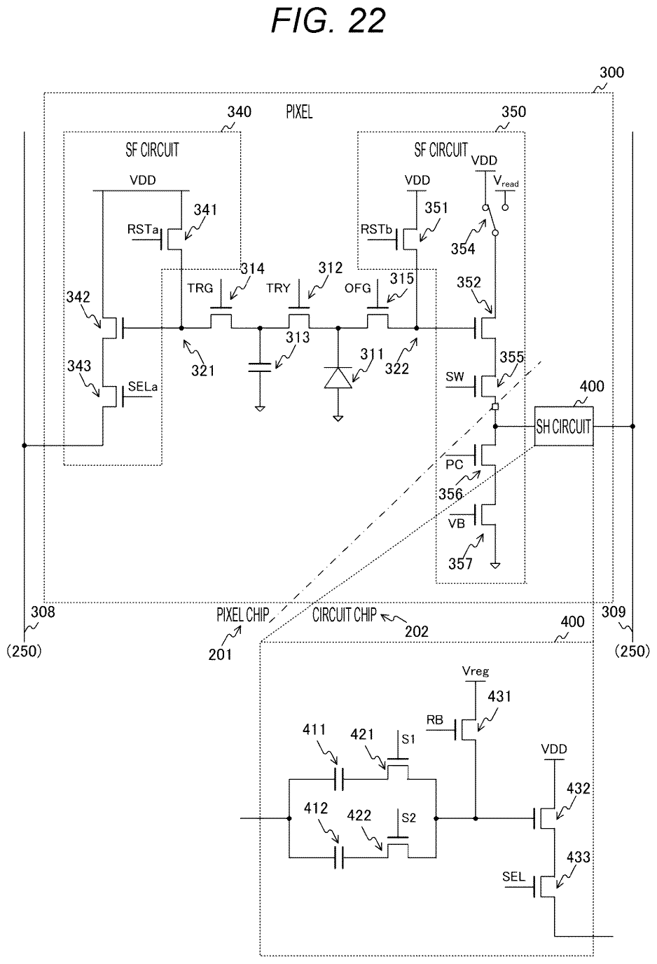

FIG. 22 is a circuit diagram illustrating a configuration example of a pixel 300 according to the sixth embodiment of the present technology. In the pixel 300 of the sixth embodiment, the selection transistor 353 is not disposed. Furthermore, the pixel 300 of the sixth embodiment is different from that of the first embodiment in further including a switch 354, a switching transistor 355, a precharge transistor 356, a current source transistor 357, and the sample hold circuit 400. The switch 354, the switching transistor 355, the precharge transistor 356, and the current source transistor 357 are disposed in the source follower circuit 350.

The switch 354 selects either the power supply voltage VDD or the voltage V_{read} under the control of the vertical scanning circuit 211 and supplies the selected voltage to the drain of the amplification transistor 352. When the sample hold circuit 400 samples and holds the level, the power supply voltage VDD is selected. On the other hand, the voltage V_{read} is selected when the level is read from the sample hold circuit 400 and AD conversion is performed for each row.

Here, the voltage _{Vread} is set to a value shown in the following formula.

V_{read}=VDD−Vgs−Vft

In the above formula, Vgs represents a gate-source voltage of the amplification transistor 352. Vft is a variation amount of the potential of the FD 322 due to the reset feedthrough of the reset transistor 351.

By switching to the voltage V_{read} at the time of reading, the amplification transistor 352 is turned off, and noise generated in the transistor can be reduced.

The switching transistor 355 opens and closes a path between the source of the amplification transistor 352 and the sample hold circuit 400 in accordance with a control signal SW from the vertical scanning circuit 211.

The precharge transistor 356 opens and closes a path between the switching transistor 355 and the current source transistor 357 in accordance with a control signal PC from the vertical scanning circuit 211.

Furthermore, the sample hold circuit 400 includes capacitive elements 411 and 412, selection transistors 421 and 422, and a reset transistor 431, an amplification transistor 432, and a selection transistor 433.

One ends of the capacitive elements 411 and 412 are commonly connected to a pre-stage node that is a connection node of the switching transistor 355 and the precharge transistor 356. The selection transistors 421 and 422 are inserted in parallel between the other ends of the capacitive elements 411 and 412 and a predetermined post-stage node.

The selection transistor 421 opens and closes a path between the capacitive element 411 and a post-stage node in accordance with a selection signal S1 received from the vertical scanning circuit 211. The selection transistor 422 opens and closes a path between the capacitive element 412 and a post-stage node in accordance with a selection signal S2 received from the vertical scanning circuit 211.

The vertical scanning circuit 211 can cause the capacitive elements 411 and 412 to hold a reset level and a signal level under the control of the selection transistors 421 and 422. Note that the capacitive elements 411 and 412 are examples of first and second capacitive elements recited in the claims.

The reset transistor 431 initializes a post-stage node in accordance with a reset signal RB received from the vertical scanning circuit 211. The amplification transistor 432 amplifies a voltage of the post-stage node. The selection transistor 433 outputs the amplified voltage signal as the pixel signal to the vertical signal line 309 in accordance with a selection signal SEL.

Furthermore, circuits and elements in the solid-state imaging element 200 are dispersedly disposed on each of stacked pixel chip 201 and circuit chip 202. For example, the elements up to the switching transistor 355 of the pixel 300 are disposed in the pixel chip 201, and the remaining elements in the pixel 300 and the circuit at the subsequent stage of the pixel 300 are disposed in the circuit chip 202. Note that the circuits and elements in the solid-state imaging element 200 can also be dispersedly disposed on three or more semiconductor chips. Furthermore, it is also possible to dispose the circuits and elements on one semiconductor chip without forming a stacked structure.

As exemplified in the drawing, a method in which the sample hold circuit 400 samples and holds the level after charge-voltage conversion is called a voltage domain method. The above-described charge domain method reduces random noise as compared with the voltage domain method, but it is difficult to achieve both miniaturization and an increase in saturation capacity. On the other hand, in the voltage domain system, it is easy to achieve both miniaturization and an increase in saturation capacitance as compared with the charge domain system, but random noise increases. By holding the overflow side level less affected by the random noise by the voltage domain method, it is possible to achieve both miniaturization and an increase in saturation capacity while suppressing the random noise. This can lead to an improvement in image quality.

In the sixth embodiment, the control of the reset signals RSTa and RSTb, the control signal OFG, and the transfer signals TRY and TRG from the exposure start to the exposure end is similar to that illustrated in FIG. 10.

Moreover, the vertical scanning circuit 211 turns on the selection transistors 421 of all the pixels by the selection signal S1 over a certain period from the time of pulse transfer of the reset signal RSTb. Therefore, the reset level Pb is sampled and held in the capacitive element 411.

Furthermore, the vertical scanning circuit 211 turns on the selection transistors 422 of all the pixels by the selection signal S2 over a certain period from the time of pulse transfer of the transfer signal TRY. Therefore, the signal level Db is sampled and held in the capacitive element 412.

Furthermore, the power supply voltage VDD is selected by the switch 354 at the time of exposure, and the voltage _{Vread} is selected at the time of reading.

Then, during the readout period, the vertical scanning circuit 211 turns on the reset transistor 431 of the selected row by the reset signal RB over the pulse period.

Immediately after the initialization of the post-stage node, the vertical scanning circuit 211 turns on the selection transistor 421 of the selected row by the selection signal S1 over a certain period. At this time, the reset levels Pa and Pb are read.

After reading the reset levels Pa and Pb, the vertical scanning circuit 211 turns on the selection transistor 421 of the selected row by the selection signal S1 over a certain period. At this time, the signal levels Da and Db are read out.

Furthermore, the selection transistors 343 and 433 of the selected row are controlled to the on state within the readout period.

As described above, according to the sixth embodiment of the present technology, the sample hold circuit 400 samples and holds the reset level Rb and the signal level Db on the overflow side, so that the image quality can be improved.

### [First Modification]

In the above-described sixth embodiment, the sample hold circuit 400 sequentially outputs the reset level Rb and the signal level Db via the vertical signal line 309, but with this configuration, it is difficult to further improve the reading speed. A solid-state imaging element 200 in a first modification of the sixth embodiment is different from that of the sixth embodiment in that a sample hold circuit 400 simultaneously outputs a reset level Rb and a signal level Db via two vertical signal lines.

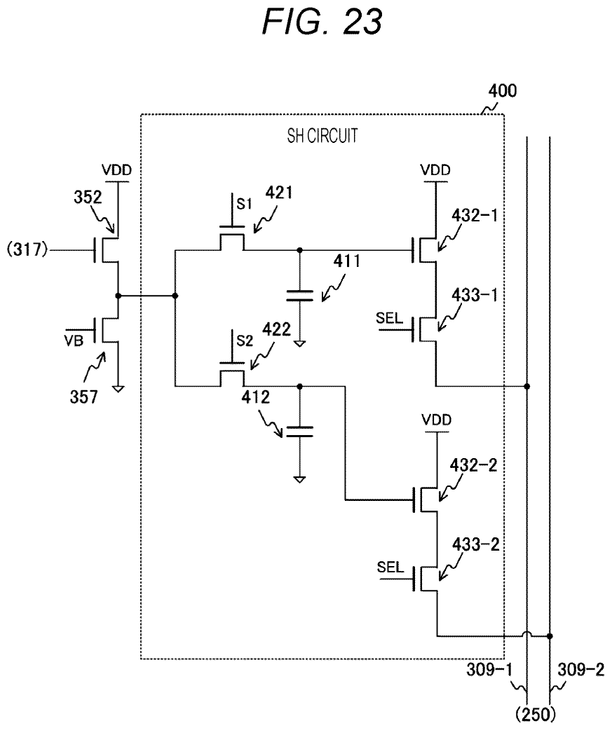

FIG. 23 is a circuit diagram illustrating a configuration example of the sample hold circuit 400 according to the first modification of the sixth embodiment of the present technology. The reset transistor 431 is eliminated from the sample hold circuit 400 of the first modification of the sixth embodiment. Furthermore, the sample hold circuit 400 includes amplification transistors 432-1 and 432-2 and selection transistors 433-1 and 433-2 instead of the amplification transistor 432 and the selection transistor 433.

Furthermore, the switch 354, the switching transistor 355, and the precharge transistor 356 are not disposed in the source follower circuit 350 in the preceding stage. Furthermore, in addition to a vertical signal lines 308 (not illustrated), vertical signal lines 309-1 and 309-2 are wired for each column.

The selection transistor 421 opens and closes a path between a connection node of the amplification transistor 352 and the current source transistor 357 and one end of the capacitive element 411. The selection transistor 422 opens and closes a path between a connection node of the amplification transistor 352 and the current source transistor 357 and one end of the capacitive element 412.

The amplification transistor 432-1 amplifies the voltage at one end of the capacitive element 411, and the selection transistor 433-1 outputs a pixel signal to the vertical signal line 309-1. The amplification transistor 432-2 amplifies the voltage at one end of the capacitive element 412, and the selection transistor 433-2 outputs a pixel signal to the vertical signal line 309-2. Furthermore, in the column signal processing circuit 260, three ADCs 261 are disposed for each column.

The sample hold circuit 400 can simultaneously output the reset level Rb and the signal level Db via the vertical signal lines 309-1 and 309-2. Furthermore, as compared with the sixth embodiment, it is not necessary to initialize the post-stage node by the reset transistor 341 at the time of reading, so that the reading speed can be further improved.

As described above, according to the first modification of the sixth embodiment of the present technology, since the sample hold circuit 400 outputs the reset level Rb and the signal level Db via the two vertical signal lines, initialization of the post-stage node becomes unnecessary at the time of reading. Therefore, the reading speed can be further improved.

### [Second Modification]

In the above-described sixth embodiment, the selection transistors 421 and 422 are inserted in parallel between the capacitive elements 411 and 422 and the post-stage node, but in this configuration, it is difficult to further reduce the circuit scale. A solid-state imaging element 200 of a second modification of the sixth embodiment is different from that of the sixth embodiment in that selection transistors 421 and 422 are connected in series.

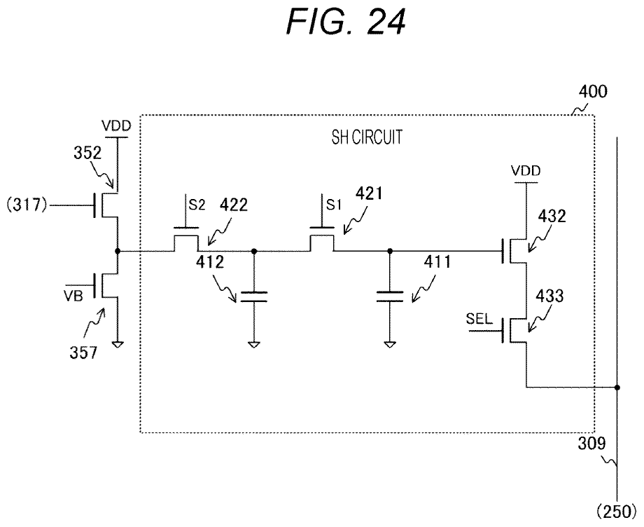

FIG. 24 is a circuit diagram illustrating a configuration example of a sample hold circuit 400 according to the second modification of the sixth embodiment of the present technology. A reset transistor 431 is eliminated from the sample hold circuit 400 of the second modification of the sixth embodiment.

Furthermore, the switch 354, the switching transistor 355, and the precharge transistor 356 are not disposed in the source follower circuit 350 in the preceding stage.

Furthermore, the selection transistors 421 and 422 are inserted in series between a connection node of the amplification transistor 352 and the current source transistor 357, and the amplification transistor 432. The capacitive element 412 is inserted between a connection node of the selection transistors 421 and 422, and a ground node, and the capacitive element 411 is inserted between a connection node of the selection transistor 421 and the amplification transistor 432, and a ground node.

The control method of this sample hold circuit 400 is described in, for example, “Chen Xu et al., A Stacked Global-Shutter CMOS Imager with SC-Type Hybrid-GS Pixel and Self-Knee Point Calibration Single-Frame HDR and On-Chip Binarization Algorithm for Smart Vision Applications IS SCC2019”.

As described above, according to the second modification of the sixth embodiment of the present technology, since the selection transistors 421 and 422 are connected in series, the reset transistor 431 can be eliminated.

### [Third Modification]

In the above-described sixth embodiment, the selection transistors 421 and 422 are inserted in parallel between the capacitive elements 411 and 422 and the post-stage node, but in this configuration, it is difficult to further reduce the circuit scale. A solid-state imaging element 200 in a third modification of the sixth embodiment is different from that of the sixth embodiment in that a selection transistor 422 and a capacitive element 411 are connected in series, and a capacitive element 412 is inserted between a connection node and a ground node thereof.

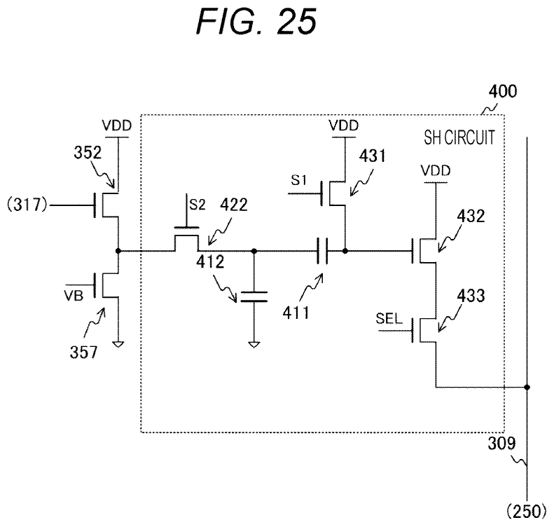

FIG. 25 is a circuit diagram illustrating a configuration example of a sample hold circuit 400 according to the third modification of the sixth embodiment of the present technology. A selection transistor 421 is eliminated from the sample hold circuit 400 of the third modification of the sixth embodiment.

Furthermore, the switch 354, the switching transistor 355, and the precharge transistor 356 are not disposed in the source follower circuit 350 in the preceding stage.

The selection transistor 422 and the capacitive element 411 are inserted in series between a connection node of the amplification transistor 352 and the current source transistor 357, and the post-stage node. The capacitive element 412 is inserted between a connection node of the selection transistor 422 and the capacitive element 411 and a ground terminal.

The control method of this sample hold circuit 400 is described in, for example, “Jae-kyu Lee, et al., A 2.1e—Temporal Noise and −105 dB Parasitic Light Sensitivity Backside-Illuminated 2.3 μm-Pixel Voltage-Domain Global Shutter CMOS Image Sensor Using High-Capacity DRAM Capacitor Technology, ISSCC 2020”.

As described above, according to the third modification of the sixth embodiment of the present technology, since the selection transistor 422 and the capacitive element 411 are connected in series and the capacitive element 412 is inserted between the connection node and the ground node, the selection transistor 421 can be reduced.

### 7. Seventh Embodiment

In the first embodiment described above, the sample hold circuit 400 samples and holds the reset level Rb and the signal level Db, but with this configuration, it is difficult to further expand the dynamic range. A solid-state imaging element 200 of the seventh embodiment is different from that of the sixth embodiment in that the conversion efficiency is switched in multiple stages.

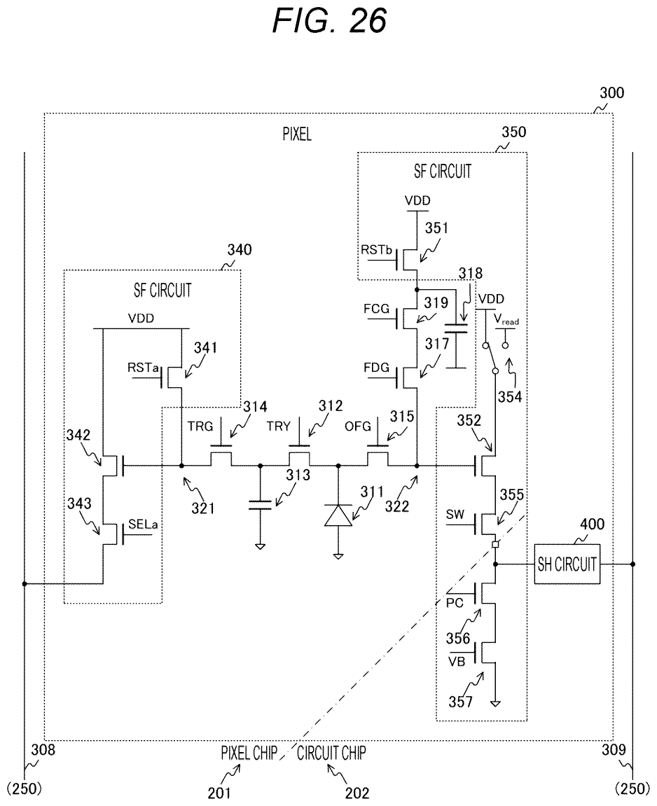

FIG. 26 is a circuit diagram illustrating a configuration example of a pixel 300 according to the seventh embodiment of the present technology. This pixel 300 of the seventh embodiment differs from that of the sixth embodiment in further including an FCG transistor 319, an FDG transistor 317 and an MIM capacitor 318. Furthermore, a transistor and a capacitor are added in the sample hold circuit 400.

The FCG transistor 319 opens and closes a path between a reset transistor 351 and the FDG transistor 317 in accordance with a control signal FCG from a vertical scanning circuit 211. Furthermore, one end of the MIM capacitor 318 is connected to a connection node between the reset transistor 351 and the FCG transistor 319. The FDG transistor 317 opens and closes a path between the FCG transistor 319 and an FD 322 in accordance with a control signal FDG.

A case where only the FDG transistor 317 of the FCG transistor 319 and the FDG transistor 317 is in the on state is lower in conversion efficiency than a case where both the transistors are in the off state. Furthermore, in a case where both the FCG transistor 319 and the FDG transistor 317 are turned on, the conversion efficiency is lower than in a case where only the FDG transistor 317 is turned on. As described above, the conversion efficiency can be switched in three stages by the control of each of the FCG transistor 319 and the FDG transistor 317. The highest conversion efficiency is referred to as “high convert gain (HCG)”, and the lowest conversion efficiency is referred to as “low convert gain (LCG)”. The intermediate conversion efficiency between the HCG and the LCG is referred to as “middle convert gain (MCG)”.

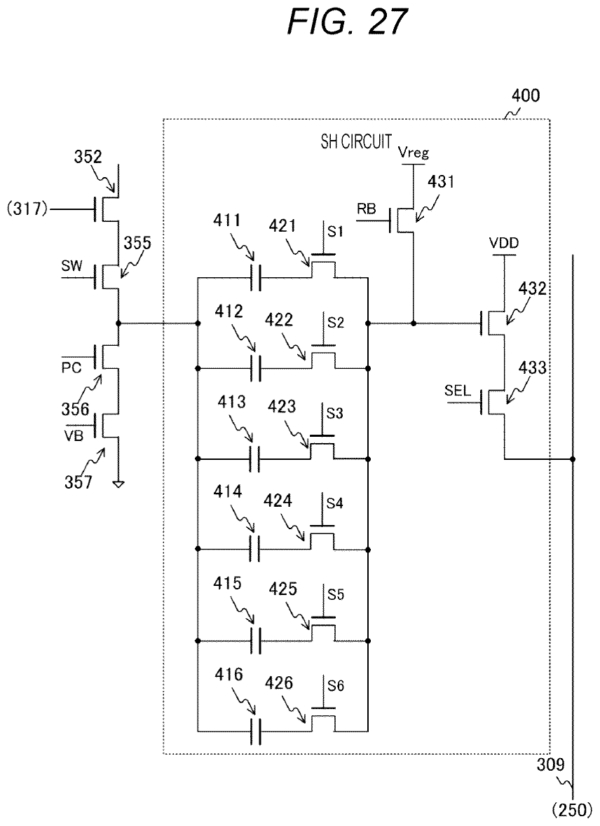

FIG. 27 is a circuit diagram illustrating a configuration example of a sample hold circuit 400 according to the seventh embodiment of the present technology. The sample hold circuit 400 of the seventh embodiment is different from that of the sixth embodiment in further including capacitive elements 413, 414, 415, 416, and selection transistors 423, 424, 425, and 426.

The connection configuration of capacitive elements 411 and 412, and selection transistors 421 and 422 is similar to that of the sixth embodiment.

The capacitive elements 413, 414, 415, and 416 have their respective one ends commonly connected to the pre-stage node. The selection transistor 423 opens and closes a path between the other end of the capacitive element 413 and a post-stage node in accordance with a selection signal S3 from the vertical scanning circuit 211. The selection transistor 424 opens and closes a path between the other end of the capacitive element 414 and a post-stage node in accordance with a selection signal S4 from the vertical scanning circuit 211. The selection transistor 425 opens and closes a path between the other end of the capacitive element 415 and a post-stage node in accordance with a selection signal S5 from the vertical scanning circuit 211. The selection transistor 426 opens and closes a path between the other end of the capacitive element 416 and a post-stage node in accordance with a selection signal S6 from the vertical scanning circuit 211.

Note that the capacitive elements 413 and 414 are examples of third and fourth capacitive elements recited in the claims.

The vertical scanning circuit 211 can cause the capacitive elements 411 to 416 to hold six different levels under the control of the selection transistors 421 to 426.

The column signal processing circuit 260 performs CDS processing for each conversion efficiency of each stage and synthesizes these pixel signals. Therefore, the dynamic range can be expanded.

Note that the switching transistor 355 can also be eliminated. Furthermore, although the conversion efficiency is switched in three stages, the conversion efficiency may be switched in two stages or in multiple stages of four or more stages. In this case, the number of capacitive elements and selection transistors is adjusted according to the number of stages of conversion efficiency. Furthermore, the first modification of the sixth embodiment can be applied to the seventh embodiment.

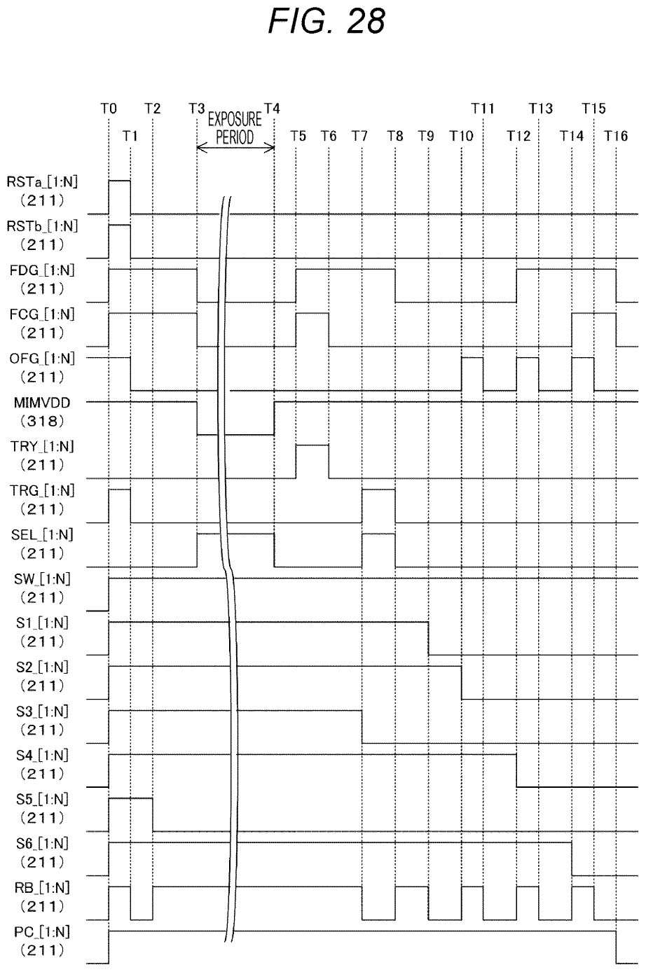

FIG. 28 is a timing chart illustrating an example of exposure control of the solid-state imaging element according to the seventh embodiment of the present technology.

During a period from timing T0 immediately before the exposure start to timing T1, the vertical scanning circuit 211 supplies high-level reset signals RSTa, RSTb, and RB and a transfer signal TRG to all the pixels. Therefore, the exposure starts in all the pixels.

Furthermore, the vertical scanning circuit 211 sets control signals FDG and FCG, selection signals S1 to S6, and control signals PC of all the pixels to the high level at timing T0, and sets control signals OFG and reset signals RB of all the pixels to the low level at timing T1.

Then, the vertical scanning circuit 211 sets the selection signals S5 of all the pixels to the low level at timing T2. Therefore, a reset level Pb corresponding to the LCG is sampled and held.

At timing T3 at the start of exposure, the vertical scanning circuit 211 sets the control signals FDG and FCG to the low level and sets a selection signal SEL to the high level for all the pixels. As a result, MIMVDD, which is a level of the MIM capacitor 318, drops.

At timing T4 when the exposure ends, the vertical scanning circuit 211 returns the selection signals SEL of all the pixels to the low level. Therefore, the MIMVDD increases.

Then, the vertical scanning circuit 211 sets the control signals FDG and FCG and the transfer signal TRY to the high level at timing T5, and sets the control signal FCG and the transfer signal TRY to the low level at timing T6 for all the pixels. As a result, a charge is transferred to an analog memory 313.

Then, the vertical scanning circuit 211 sets the transfer signal TRG and the selection signal SEL to the high level at timing T7, and sets the selection signal S3 and the reset signal RB to the low level for all the pixels. The vertical scanning circuit 211 sets the transfer signal TRG and the selection signal SEL to the low level, and sets the reset signal RB to the high level at timing T8 for all the pixels. Therefore, the reset level Pb corresponding to the MCG is sampled and held.

Then, the vertical scanning circuit 211 sets the selection signal S1 and the reset signal RB to the low level at timing T9, and sets the control signal OFG and the reset signal RB to the high level at timing T10 for all the pixels to set the selection signal S2 to the low level. Therefore, the reset level Pb corresponding to the HCG is sampled and held.

Then, the vertical scanning circuit 211 sets the control signal OFG and the reset signal RB to the low level at timing T11, and sets the control signals FDG and OFG and the reset signal RB to the high level at timing T12 for all the pixels to set the selection signal S4 to the low level. Therefore, a signal level Db corresponding to the HCG is sampled and held.

Then, the vertical scanning circuit 211 sets the control signal OFG and the reset signal RB to the low level at timing T13, and sets the control signals FCG and OFG and the reset signal RB to the high level at timing T14 for all the pixels to set the selection signal S6 to the low level. Therefore, the signal level Db corresponding to the MCG is sampled and held.

Then, the vertical scanning circuit 211 sets the control signal OFG and the reset signal RB to the low level at timing T15, and sets the control signals FDG, FCG, and PC to the low level at timing T16 for all the pixels. Therefore, the signal level Db corresponding to the LCG is sampled and held.

At the time of reading, in parallel with reading of a reset level Pa and a signal level Da of the selected row, the reset level Pb corresponding to the HCG, the MCG, and the LCG and the signal level Db corresponding to the HCG, the MCG, and the LCG are sequentially read.

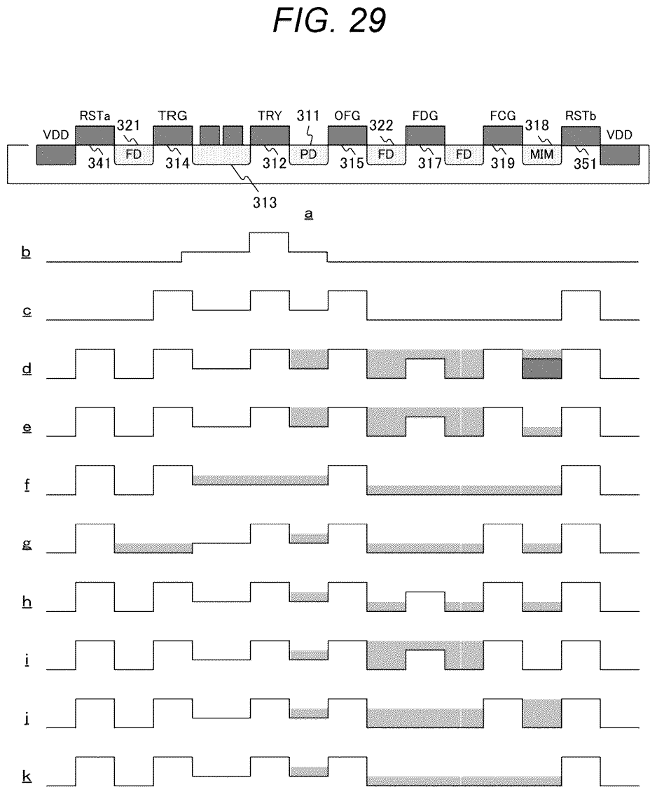

FIG. 29 is an example of a potential diagram of the pixel according to the seventh embodiment of the present technology. In the drawing, a illustrates a cross-sectional view of the pixel 300.

In the drawing, b is a potential diagram illustrating a state of the pixel 300 being exposed. As illustrated in b of the drawing, the photoelectric conversion element 311 is initialized.

In the drawing, c is a potential diagram illustrating a state of the pixel 300 when the reset level Pb corresponding to the LCG is held.

In the drawing, d is a potential diagram illustrating a state of the pixel 300 being exposed. As illustrated in d of the drawing, a charge having overflowed from the photoelectric conversion element 311 is transferred to the FD or the MIM capacitor 318 at the subsequent stage of the OFG transistor 315. Furthermore, the level of the MIM capacitor 318 drops at the time of exposure.

In the drawing, e is a potential diagram illustrating a state of the pixel 300 at the end of exposure. As illustrated in e of the drawing, the level of the MIM capacitor 318 is boosted.

In the drawing, f is a potential diagram illustrating a state of the pixel 300 immediately after exposure. As illustrated in f of the drawing, the transfer transistor 312, the FDG transistor 317, and the FCG transistor 319 are turned on, and a dark current of the FD is averaged.

In the drawing, g is a potential diagram illustrating a state of the pixel 300 when the signal level Db and the reset level Pb corresponding to the MCG are held. As illustrated in g of the drawing, a charge is transferred to the FD 321, and the FDG transistor 317 is turned on. Furthermore, in g of the drawing, it is assumed that the capacitance of the MIM capacitor 318 is small, and all the charges of the photoelectric conversion element 311 cannot be fully received, and the charges remain in the photoelectric conversion element 311.

In the drawing, h is a potential diagram illustrating a state of the pixel 300 when the reset level Pb corresponding to the HCG is held.

In the drawing, i is a potential diagram illustrating a state of the pixel 300 when the signal level Db corresponding to the HCG is held. As exemplified in i of the drawing, the charges remaining in the photoelectric conversion element 311 are transferred to the FD 322.

In the drawing, j is a potential diagram illustrating a state of the pixel 300 when the signal level Db corresponding to the MCG is held.

In the drawing, k is a potential diagram illustrating a state of the pixel 300 when the signal level Db corresponding to the LCG is held.

As described above, according to the seventh embodiment of the present technology, since the conversion efficiency is switched in three stages, the dynamic range can be expanded as compared with the sixth embodiment.

### 8. Application Example to Mobile Body

The technology according to the present disclosure (the present technology) can be applied to various products. For example, the technology according to the present disclosure may be implemented in the form of a device to be mounted on a mobile body of any kind, such as an automobile, an electric vehicle, a hybrid electric vehicle, a motorcycle, a bicycle, a personal mobility, an airplane, a drone, a vessel, or a robot.

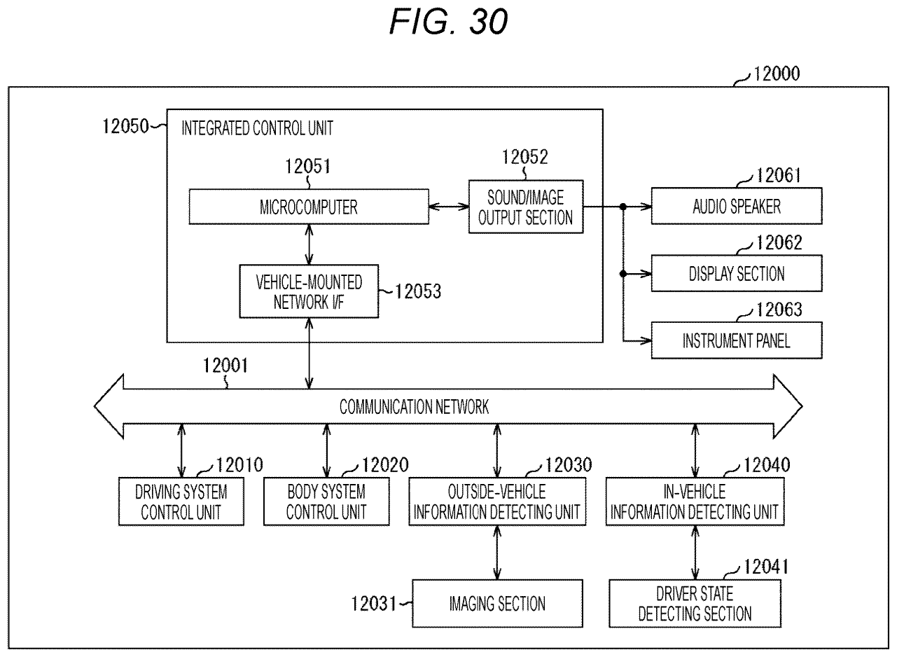

FIG. 30 is a block diagram illustrating a schematic configuration example of a vehicle control system as an example of a mobile body control system to which the technology according to the present disclosure can be applied.

The vehicle control system 12000 includes a plurality of electronic control units connected to each other via a communication network 12001. In the example depicted in FIG. 30, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as functional configurations of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020, on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 30, an audio speaker 12061, a display section 12062, and an instrument panel 12063 are illustrated as the output device. The display section 12062 may, for example, include at least one of an on-board display and a head-up display.

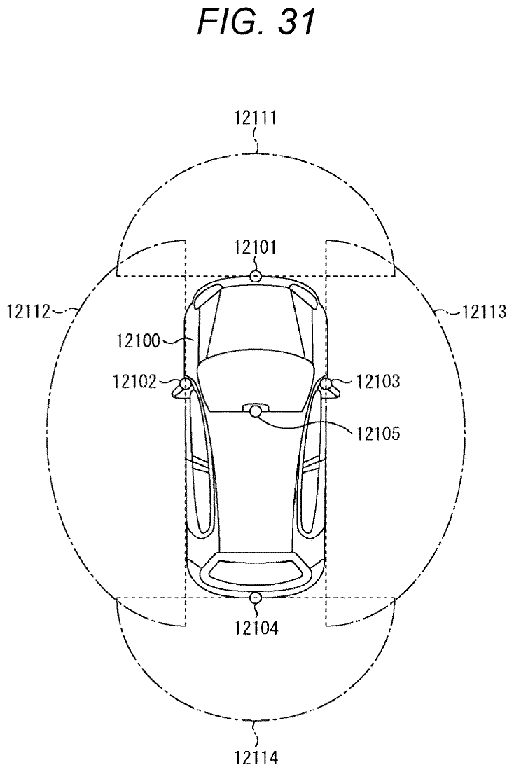

FIG. 31 is a diagram illustrating an example of an installation position of the imaging section 12031.

In FIG. 31, the imaging section 12031 includes imaging sections 12101, 12102, 12103, 12104, 12105.

The imaging sections 12101, 12102, 12103, 12104, 12105 are provided, for example, at positions such as a front nose, a sideview mirror, a rear bumper, a back door, and an upper portion of a windshield in the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 31 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure is applicable to the imaging section 12031, for example, among the configurations described above. Specifically, the imaging device 100 in FIG. 1 can be applied to the imaging section 12031. By applying the technology according to the present disclosure to the imaging section 12031, the dynamic range can be expanded by the global shutter method, and a more easily viewable captured image can be obtained, thus enabling a reduction in driver's fatigue.

Note that the embodiments described above show examples for embodying the present technology, and the respective matters in the embodiments and the respective matters specifying the invention in the claims have correspondence relationships. Similarly, the matters specifying the invention in the claims and the matters with the same names in the embodiments of the present technology have correspondence relationships, respectively. However, the present technology is not limited to the embodiments, and can be embodied by applying various modifications to the embodiments without departing from the scope of the present technology.

Note that the effects described in the present specification are merely examples and are not limited, and other effects may also be achieved.

Note that the present technology may also have the following configuration.
(1) A solid-state imaging element including:
a first transfer transistor that transfers a charge from a photoelectric conversion element to a charge holding section;
a second transfer transistor that transfers a charge from one of the charge holding section and the photoelectric conversion element to a first floating diffusion layer; and
an overflow gate that causes a second floating diffusion layer to hold a charge having overflowed from the photoelectric conversion element.
(2) The solid-state imaging element according to (1) described above,
in which the second transfer transistor transfers a charge from the charge holding section to the first floating diffusion layer, and
the overflow gate causes the second floating diffusion layer to hold a charge having overflowed from the photoelectric conversion element.
(3) The solid-state imaging element according to (2) described above, further including:
a first source follower circuit that amplifies and outputs a voltage of the first floating diffusion layer; and
a second source follower circuit that amplifies and outputs a voltage of the second floating diffusion layer.
(4) The solid-state imaging element according to (2) described above, further including
a source follower circuit that amplifies and outputs a voltage of the second floating diffusion layer,
in which the first floating diffusion layer is connected to the second floating diffusion layer.
(5) The solid-state imaging element according to (2) described above, further including:
a conversion efficiency control transistor that opens and closes a path between the first floating diffusion layer and a third floating diffusion layer;
a connection transistor that opens and closes a path between the second floating diffusion layer and the third floating diffusion layer; and
a source follower circuit that amplifies and outputs a voltage of the first floating diffusion layer.
(6) The solid-state imaging element according to (5) described above, in which
a capacitance value of the third floating diffusion layer is 10 times or more a capacitance value of any one of the first and second floating diffusion layers.
(7) The solid-state imaging element according to (5) or (6) described above, in which
a plurality of pixel circuits shares the first floating diffusion layer and the source follower circuit, and
the photoelectric conversion element, the second and third floating diffusion layers, the charge holding section, the first and second transfer transistors, the overflow gate, and the conversion efficiency control transistor are disposed in each of the plurality of pixel circuits.
(8) The solid-state imaging element according to (2) described above, further including:
a first source follower circuit that amplifies a voltage of the first floating diffusion layer and outputs the amplified voltage as a first voltage;
a second source follower circuit that amplifies a voltage of the second floating diffusion layer and outputs the amplified voltage as a second voltage; and
a sample hold circuit that holds the second voltage.
(9) The solid-state imaging element according to (8) described above, in which
the second voltage includes: a reset level when the second floating diffusion layer is initialized; and a signal level according to an amount of charges accumulated in the second floating diffusion layer, and
the sample hold circuit includes:
a first capacitive element that holds the reset level; and
a second capacitive element that holds the signal level.
(10) The solid-state imaging element according to (8) described above, in which
the second voltage includes: a reset level when the second floating diffusion layer is initialized; and a signal level according to an amount of charges accumulated in the second floating diffusion layer,
the reset level includes first and second reset levels having conversion efficiencies different from each other for converting charges into voltages,
the signal level includes first and second signal levels having the conversion efficiencies different from each other, and
the sample hold circuit includes a plurality of capacitive elements that holds the first and second reset levels and the first and second signal levels, respectively.
(11) The solid-state imaging element according to (1) described above, in which
the second transfer transistor transfers a charge from the photoelectric conversion element to the first floating diffusion layer,
the first transfer transistor transfers a charge having overflowed from the photoelectric conversion element to the charge holding section, and
the overflow gate transfers the overflowed charge from the charge holding section to the second floating diffusion layer and causes the second floating diffusion layer to hold the charge.
(12) An imaging device including:
a first transfer transistor that transfers a charge from a photoelectric conversion element to a charge holding section;
a second transfer transistor that transfers a charge from one of the charge holding section and the photoelectric conversion element to a first floating diffusion layer;
an overflow gate that causes the second floating diffusion layer to hold a charge having overflowed from the photoelectric conversion element; and
a signal processing circuit that synthesizes a first pixel signal according to a voltage of the first floating diffusion layer and a second pixel signal according to a voltage of the second floating diffusion layer.
(13) A control method of a solid-state imaging element, the control method including:
a first transfer procedure in which a first transfer transistor transfers a charge from a photoelectric conversion element to a charge holding section;
a second transfer procedure in which a second transfer transistor transfers a charge from one of the charge holding section and the photoelectric conversion element to a first floating diffusion layer; and
a procedure in which an overflow gate causes a second floating diffusion layer to hold a charge having overflowed from the photoelectric conversion element.

### REFERENCE SIGNS LIST

100 Imaging device
110 Imaging lens
120 Recording section
130 Imaging control section
200 Solid-state imaging element
201 Pixel chip
202 Circuit chip
211 Vertical scanning circuit
212 Timing control circuit
213 DAC
220 Pixel array section
221 Pixel block
250 Load MOS circuit block
251 Load MOS transistor
260 Column signal processing circuit
261 ADC
262 Digital signal processing circuit
263 Selector
264 Memory
265 Subtractor
266 Synthesis processing section
300 Pixel
310-1 to 310-4 Pixel circuit
311 Photoelectric conversion element
312, 314 Transfer transistor
313 Analog memory
315 OFG transistor
316 Connection transistor
317 FDG transistor
318 Metal-insulator-metal (MIM) capacitor
319 FCG transistor
321, 322, 323 FD
340, 350 Source follower circuit
341, 351, 431 Reset transistor
342, 352, 432, 432-1, 432-2 Amplification transistor
343, 353, 421 to 426, 433, 433-1, 433-2 Selection transistor
354 Switch
355 Switching transistor
356 Precharge transistor
357 Current source transistor
400 Sample hold circuit
411 to 416 Capacitive element
12031 Imaging section

1. A solid-state imaging element comprising:
a first transfer transistor that transfers a charge from a photoelectric conversion element to a charge holding section;
a second transfer transistor that transfers a charge from one of the charge holding section and the photoelectric conversion element to a first floating diffusion layer; and
an overflow gate that causes a second floating diffusion layer to hold a charge having overflowed from the photoelectric conversion element.

2. The solid-state imaging element according to claim 1, wherein
the second transfer transistor transfers a charge from the charge holding section to the first floating diffusion layer, and
the overflow gate causes the second floating diffusion layer to hold a charge having overflowed from the photoelectric conversion element.

3. The solid-state imaging element according to claim 2, further comprising:
a first source follower circuit that amplifies and outputs a voltage of the first floating diffusion layer; and
a second source follower circuit that amplifies and outputs a voltage of the second floating diffusion layer.

4. The solid-state imaging element according to claim 2, further comprising
a source follower circuit that amplifies and outputs a voltage of the second floating diffusion layer, wherein
the first floating diffusion layer is connected to the second floating diffusion layer.

5. The solid-state imaging element according to claim 2, further comprising:
a conversion efficiency control transistor that opens and closes a path between the first floating diffusion layer and a third floating diffusion layer;
a connection transistor that opens and closes a path between the second floating diffusion layer and the third floating diffusion layer; and
a source follower circuit that amplifies and outputs a voltage of the first floating diffusion layer.

6. The solid-state imaging element according to claim 5, wherein
a capacitance value of the third floating diffusion layer is 10 times or more a capacitance value of any one of the first and second floating diffusion layers.

7. The solid-state imaging element according to claim 5, wherein
a plurality of pixel circuits shares the first floating diffusion layer and the source follower circuit, and
the photoelectric conversion element, the second and third floating diffusion layers, the charge holding section, the first and second transfer transistors, the overflow gate, and the conversion efficiency control transistor are disposed in each of the plurality of pixel circuits.

8. The solid-state imaging element according to claim 2, further comprising:
a first source follower circuit that amplifies a voltage of the first floating diffusion layer and outputs the amplified voltage as a first voltage;
a second source follower circuit that amplifies a voltage of the second floating diffusion layer and outputs the amplified voltage as a second voltage; and
a sample hold circuit that holds the second voltage.

9. The solid-state imaging element according to claim 8, wherein
the second voltage includes: a reset level when the second floating diffusion layer is initialized; and a signal level according to an amount of charges accumulated in the second floating diffusion layer, and
the sample hold circuit includes:
a first capacitive element that holds the reset level; and
a second capacitive element that holds the signal level.

10. The solid-state imaging element according to claim 8, wherein
the second voltage includes: a reset level when the second floating diffusion layer is initialized; and a signal level according to an amount of charges accumulated in the second floating diffusion layer,
the reset level includes first and second reset levels having conversion efficiencies different from each other for converting charges into voltages,
the signal level includes first and second signal levels having the conversion efficiencies different from each other, and
the sample hold circuit includes a plurality of capacitive elements that holds the first and second reset levels and the first and second signal levels, respectively.

11. The solid-state imaging element according to claim 1, wherein
the second transfer transistor transfers a charge from the photoelectric conversion element to the first floating diffusion layer,
the first transfer transistor transfers a charge having overflowed from the photoelectric conversion element to the charge holding section, and
the overflow gate transfers the overflowed charge from the charge holding section to the second floating diffusion layer and causes the second floating diffusion layer to hold the charge.

12. An imaging device comprising:
a first transfer transistor that transfers a charge from a photoelectric conversion element to a charge holding section;
a second transfer transistor that transfers a charge from one of the charge holding section and the photoelectric conversion element to a first floating diffusion layer;
an overflow gate that causes the second floating diffusion layer to hold a charge having overflowed from the photoelectric conversion element; and
a signal processing circuit that synthesizes a first pixel signal according to a voltage of the first floating diffusion layer and a second pixel signal according to a voltage of the second floating diffusion layer.

13. A control method of a solid-state imaging element, the control method comprising:
a first transfer procedure in which a first transfer transistor transfers a charge from a photoelectric conversion element to a charge holding section;
a second transfer procedure in which a second transfer transistor transfers a charge from one of the charge holding section and the photoelectric conversion element to a first floating diffusion layer; and
a procedure in which an overflow gate causes a second floating diffusion layer to hold a charge having overflowed from the photoelectric conversion element.
